(19) United States
(12) Patent Application Publication
(10) Pub. No.: US 2009/0231240 A1
(43) Pub. Date: Sep. 17, 2009

(54) ORGANIC ELECTROLUMINESCENT ELEMENT AND DISPLAY DEVICE

(75) Inventors: Hidekazu Hirose, Kanagawa (JP); Koji Horiba, Kanagawa (JP); Takeshi Agata, Kanagawa (JP); Katsuhiro Sato, Kanagawa (JP)

Correspondence Address: FILDES & OUTLAND, P.C., 20916 MACK AVENUE, SUITE 2, GROSSE POINTE WOODS, MI, 48236, US

(73) Assignee: FUJI XEROX CO., LTD., Tokyo (JP)

(21) Appl. No.: 12/237,517

(22) Filed: Sep. 25, 2008

(30) Foreign Application Priority Data
Mar. 17, 2008 (JP) 2008-068361

(51) Int. Cl. G09G 3/30; H01J 1/62

(52) U.S. Cl. 345/76; 313/504

(57) ABSTRACT

An organic electroluminescent element comprising an anode and a cathode that form a pair of electrodes, and at least one organic compound layer sandwiched between the pair of electrodes, at least one of the electrodes being transparent or translucent, and the organic compound layer(s) containing, at least one charge-transporting polyester composed of repeating units represented by Formula (I-1) and Formula (I-2) as a partial structure (wherein X is represented by Formula (III)), and a display device including the same are provided.

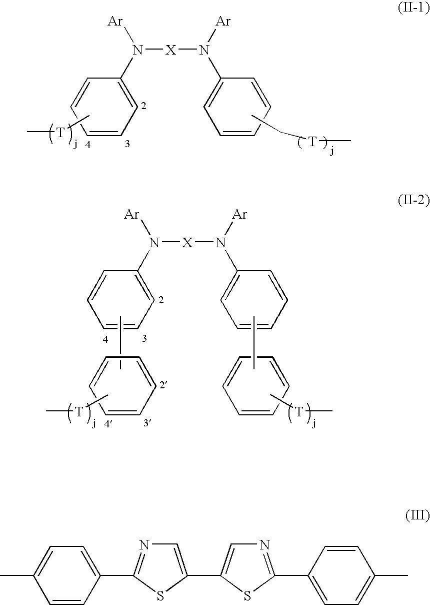

### CROSS-REFERENCE TO RELATED APPLICATION

This application is based on and claims priority under 35 USC 119 from Japanese Patent Application No. 2008-068361 filed Mar. 17, 2008.

### BACKGROUND

1. Technical Field

The present invention relates to an organic electroluminescent element and a display device using the same.

2. Related Art

Electroluminescent elements are promising for a wide range of applications because they are self-luminescent fully solid-state elements with high visibility and resistance to impact. Currently, although components and the like using inorganic fluorescent materials are predominant and widely used, an alternating voltage of 200 V or more at 50 Hz to 1000 Hz is necessary for operation thereof. Research into organic electroluminescent elements using organic compounds first used single crystals of anthracene and the like, but the film thickness was approximately 1 mm, and a driving voltage of 100 V or more was required. Subsequently, thin films have been developed by a vapor deposition method.

The luminescence of these elements is due to a phenomenon in which an electron is injected from one electrode and a hole is injected from another electrode, whereby a fluorescent material in the element is excited to a high energy level, and when the excited fluorescent material returns to a ground state, excessive energy is emitted as light; however, these elements have not been applied to actual products yet.

In recent years, electroluminescent elements composed of polymer materials rather than low molecular weight compounds have been studied and developed. Examples of these electroluminescent elements include conductive polymer elements such as poly(p-phenylene vinylene), elements composed of a polymer having triphenylamine at a side chain of polyphosphazene, and elements composed of hole-transporting polyvinyl carbazole mixed with an electron-transporting material and a fluorescent dye.

As an organic electroluminescent element which is easy to produce, and which has sufficient luminance and excellent durability, an organic electroluminescent element has been disclosed that includes an organic compound layer made of a hole-transporting polyester composed of repeating units containing, as a partial structure, at least one structure selected from specific amine structures.

To simplify production, improve workability, achieve suitably large areas, and reduce costs, the element is preferably produced by an application method. It has been disclosed that elements can be produced by a casting method. For film formation from a solution of a polymer material, polyvinyl carbazole is commonly used.

### SUMMARY

According to an aspect of the invention, there is provided an organic electroluminescent element comprising an anode and a cathode that form a pair of electrodes, and at least one organic compound layer sandwiched between the pair of electrodes, at least one of the electrodes being transparent or translucent, and the at least one organic compound layer containing at least one charge-transporting polyester represented by the following Formula (I-1) or Formula (I-2):

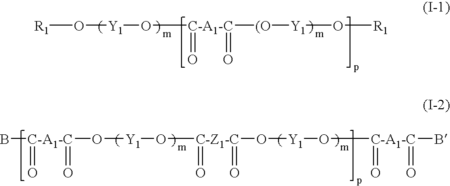

in Formula (I-1) and Formula (I-2), A₁ represents at least one structure selected from the structures represented by the following Formula (II-1) and Formula (II-2); R₁ represents a substituted or unsubstituted monovalent polynuclear aromatic hydrocarbon group having 2 to 10 aromatic rings, a substituted or unsubstituted monovalent condensed aromatic hydrocarbon group having 2 to 10 aromatic rings, a monovalent straight-chain hydrocarbon group having 1 to 6 carbon atoms, a monovalent branched hydrocarbon group having 2 to 10 carbon atoms, or a hydroxyl group; Y₁ represents a divalent alcohol residue; Z₁ represents a divalent carboxylic acid residue; m represents an integer of from 1 to 5; p represents an integer of from 5 to 5000; and B and B′ indicate groups represented by —O—(Y₁—O)ₘ—H or —O—(Y₁—O)ₘ—CO-Z₁-CO—OR₂ (wherein R₂ represents a hydrogen atom, an alkyl group, a substituted or unsubstituted aryl group, or a substituted or unsubstituted aralkyl group):

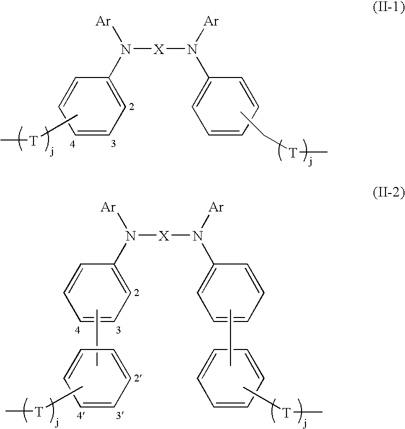

in Formula (II-1) and Formula (II-2), Ar represents a substituted or unsubstituted phenyl group, a substituted or unsubstituted monovalent polynuclear aromatic hydrocarbon having 2 to 10 aromatic rings, a substituted or unsubstituted monovalent condensed aromatic hydrocarbon having 2 to 10 aromatic rings, or a substituted or unsubstituted monovalent aromatic heterocycle; j represents 0 or 1; T represents a divalent straight-chain hydrocarbon group having 1 to 6 carbon atoms or a divalent branched hydrocarbon group having 2 to 10 carbon atoms; and X represents a group represented by the following Formula (III):

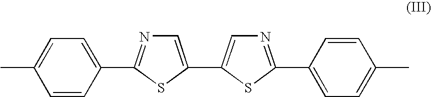

### BRIEF DESCRIPTION OF THE DRAWINGS

Exemplary embodiment(s) of the present invention will be described in detail based on the following figures, wherein:

FIG. 1 is a schematic configuration view showing an example of layer structure of organic electroluminescent element of the exemplary embodiments.

FIG. 2 is a schematic configuration view showing another example of layer structure of organic electroluminescent element of the exemplary embodiments.

FIG. 3 is a schematic configuration view showing another example of layer structure of organic electroluminescent element of the exemplary embodiments.

FIG. 4 is a schematic configuration view showing another example of layer structure of organic electroluminescent element of the exemplary embodiments.

### DETAILED DESCRIPTION

Exemplary embodiments of the invention are described in detail hereinafter. More specifically, the invention in accordance with a first aspect of the invention is an organic electroluminescent element comprising an anode and a cathode that form a pair of electrodes, and at least one organic compound layer sandwiched between the pair of electrodes, at least one of the electrodes being transparent or translucent, and the at least one organic compound layer containing at least one charge-transporting polyester represented by the following Formula (I-1) or Formula (I-2):

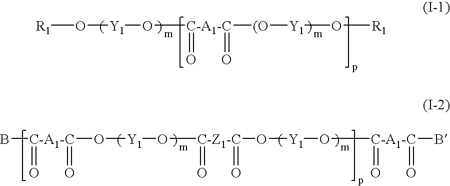

in Formula (I-1) and Formula (I-2), A₁ represents at least one structure selected from the structures represented by the following Formula (II-1) and Formula (II-2); R₁ represents a substituted or unsubstituted monovalent polynuclear aromatic hydrocarbon group having 2 to 10 aromatic rings, a substituted or unsubstituted monovalent condensed aromatic hydrocarbon group having 2 to 10 aromatic rings, a monovalent straight-chain hydrocarbon group having 1 to 6 carbon atoms, a monovalent branched hydrocarbon group having 2 to 10 carbon atoms, or a hydroxyl group; Y₁ represents a divalent alcohol residue; Z₁ represents a divalent carboxylic acid residue; m represents an integer of from 1 to 5; p represents an integer of from 5 to 5000; and B and B′ indicate groups represented by —O—(Y₁—O)ₘ—H or —O—(Y₁—O)ₘ—CO-Z₁-CO—OR₂ (wherein R₂ represents a hydrogen atom, an alkyl group, a substituted or unsubstituted aryl group, or a substituted or unsubstituted aralkyl group):

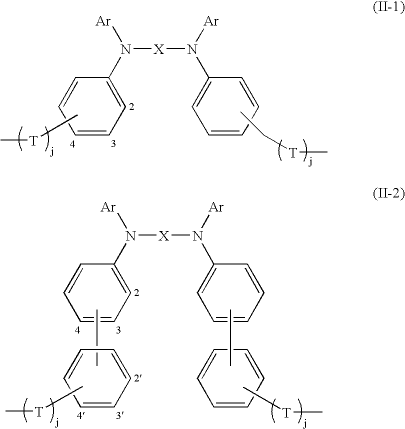

(in Formula (II-1) and Formula (II-2), Ar represents a substituted or unsubstituted phenyl group, a substituted or unsubstituted monovalent polynuclear aromatic hydrocarbon having 2 to 10 aromatic rings, a substituted or unsubstituted monovalent condensed aromatic hydrocarbon having 2 to 10 aromatic rings, or a substituted or unsubstituted monovalent aromatic heterocycle, j represents 0 or 1; T represents a divalent linear hydrocarbon group having 1 to 6 carbon atoms or a divalent branched hydrocarbon group having 2 to 10 carbon atoms, and X represents a group represented by the following Formula (III)

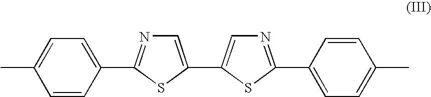

The invention in accordance with a second aspect of the invention is the organic electroluminescent element of the first aspect, wherein the organic compound layer comprises a light-emitting layer and at least one layer selected from the group consisting of an electron-transporting layer and an electron injection layer, and wherein at least one layer selected from the group consisting of the light-emitting layer, an electron-transporting layer and an electron injection layer comprises at least one charge-transporting polyester represented by Formula (I-1) or Formula (I-2).

The invention in accordance with a third aspect of the invention is the organic electroluminescent element of the first aspect, wherein the organic compound layer comprises a light-emitting layer and at least one layer selected from the group consisting of a hole-transporting layer and a hole injection layer, and wherein at least one layer selected from the group consisting of the light-emitting layer, a hole-transporting layer and a hole injection layer comprises at least one charge-transporting polyester represented by Formula (I-1) or Formula (I-2).

The invention in accordance with a fourth aspect of the invention is the organic electroluminescent element of the first aspect, wherein the organic compound layer comprises a light-emitting layer; at least one layer selected from the group consisting of a hole-transporting layer and a hole injection layer; and at least one layer selected from the group consisting of an electron-transporting layer and an electron injection layer; and wherein at least one layer selected from the group consisting of the light-emitting layer, a hole-transporting layer, a hole injection layer, an electron-transporting layer, and an electron injection layer comprises at least one charge-transporting polyester represented by Formula (I-1) or Formula (I-2).

The invention in accordance with a fifth aspect of the invention is the organic electroluminescent element of the first aspect, wherein the organic compound layer comprises only a light-emitting layer having charge-transporting properties, the light-emitting layer comprising at least one charge-transporting polyester represented by Formula (I-1) or Formula (I-2).

The invention in accordance with a sixth aspect of the invention is the organic electroluminescent element of any one of the aspects from 1 to 5, wherein Ar is a phenyl group, and Y₁ and Z₁ are selected from the groups represented by the following Formulae (IV-1) to (IV-6).

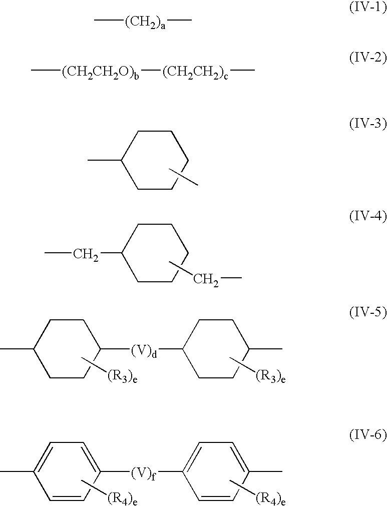

in Formulae (IV-1) to (IV-6), R₃ and R₄ each represent a hydrogen atom, a substituted or unsubstituted alkyl group having 1 to 4 carbon atoms, a substituted or unsubstituted alkoxy group having 1 to 4 carbon atoms, a substituted or unsubstituted phenyl group, a substituted or unsubstituted aralkyl group, or a halogen atom; a to c each independently represent an integer of from 1 to 10, e represents an integer of from 0 to 2; d and f each represent an integer of 0 or 1; and V represents a group represented by any one of the following Formulae (V-1) to (V-12)

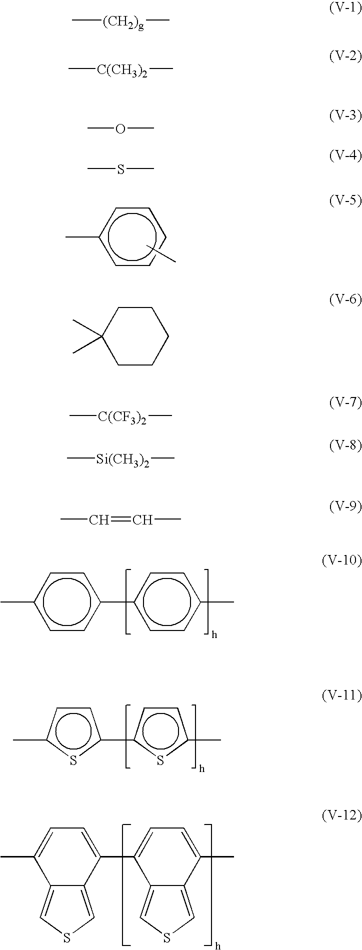

in Formulae (V-1), (V-10), (V-11), and (V-12), g represents an integer of from 1 to 20, and h represents an integer of from 0 to 10.

The invention in accordance with a seventh aspect of the invention is the organic electroluminescent element of the first aspect, wherein the organic compound layer further comprises a hole-transporting material or an electron-transporting material different from the charge-transporting polyester.

The invention in accordance with an eighth aspect of the invention is the organic electroluminescent element of the seventh aspect, wherein the hole-transporting material is any one selected from the group consisting of tetraphenylenediamine derivatives, triphenylamine derivatives, carbazole derivatives, stilbene derivatives, spirofluorene derivatives, arylhydrazone derivatives, and porphyrin-based compounds; and the electron-transporting material is any one selected from the group consisting of oxadiazole derivatives, nitro-substituted fluorenone derivatives, diphenoquinone derivatives, thiopyran dioxide derivatives, silole derivatives, organic metal chelate complexes, polynuclear or condensed aromatic cyclic compounds, perylene derivatives, triazole derivatives, and fluorenylidene methane derivatives.

The invention in accordance with a ninth aspect of the invention is the organic electroluminescent element of the aspect 2 or 4, wherein the electron injection layer comprises a metal or a metal fluoride, and/or a metal oxide.

The invention in accordance with a tenth aspect of the invention is the organic electroluminescent element of the aspect 3 or 4, wherein the hole injection layer comprises any one selected from the group consisting of triphenylamine derivatives, phenylene diamine derivatives, phthalocyanine derivatives, indanthrene derivatives, and polyalkylene dioxythiophene derivatives.

The invention in accordance with an eleventh aspect of the invention is the organic electroluminescent element of any one of the aspects from 1 to 5, wherein the organic compound layer further comprises a light-emitting compound different from the charge-transporting polyester.

The invention in accordance with a twelfth aspect of the invention is the organic electroluminescent element of the eleventh aspect, wherein the light-emitting compound is any one selected from the group consisting of organic metal chelate complexes, polynuclear or condensed aromatic cyclic compounds, perylene derivatives, coumarin derivatives, styryl arylene derivatives, silole derivatives, oxazole derivatives, oxathiazole derivatives, oxadiazole derivatives, polyparaphenylene derivatives, polyparaphenylene vinylene derivatives, polythiophene derivatives, and polyacetylene derivatives.

The invention in accordance with a thirteenth aspect of the invention is the organic electroluminescent element of any one of the aspects from 1 to 5, wherein the charge-transporting polyester further comprises a doped dye compound different from the light-emitting compound.

The invention in accordance with a fourteenth aspect of the invention is the organic electroluminescent element of the thirteenth aspect, wherein the dye compound is at least one selected from the group consisting of coumarin derivatives, 4-dicyanmethylene-2-methyl-6-(4-dimethylaminostyryl)-4H-pyran (DCM) derivatives, quinacridone derivatives, perimidone derivatives, benzopyran derivatives, rhodamine derivatives, benzothioxanthene derivatives, rubrene derivatives, porphyrin derivatives, and metal complex compounds.

The invention in accordance with a fifteenth aspect of the invention is the organic electroluminescent element of the fourteenth aspect, wherein the metal complex compound comprises at least one metal selected from the group consisting of ruthenium, rhodium, palladium, silver, rhenium, osmium, iridium, platinum, and gold.

The invention in accordance with a sixteenth aspect of the invention is a display device comprising organic electroluminescent elements and a driving unit that drives the organic electroluminescent elements, the organic electroluminescent elements having a matrix configuration or a segment configuration, and each electroluminescent element comprises a pair of transparent or translucent electrodes and an organic compound layer sandwiched between the pair of electrodes, the organic compound layer is composed of at least one layer, and at least one layer of the organic compound layer comprises at least one charge-transporting polyester of the first aspect.

<Organic Electroluminescent Element>

The organic electroluminescent element in the exemplary embodiment (hereinafter may be referred to as “organic EL element”) includes an anode and a cathode that form a pair of electrodes, and at least one organic compound layer sandwiched between the pair of electrodes, at least one of the electrodes being transparent or translucent, and the at least one organic compound layer containing at least one charge-transporting polyester represented by Formula (I-1) or Formula (I-2).

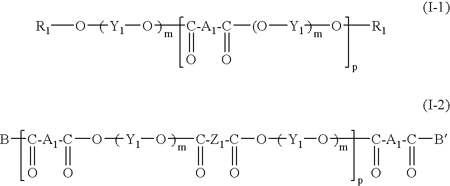

In Formula (I-1) and Formula (I-2), A₁ represents at least one structure selected from the structures represented by Formula (II-1) and Formula (II-2), R₁ represents a substituted or unsubstituted monovalent polynuclear aromatic hydrocarbon group having 2 to 10 aromatic rings, a substituted or unsubstituted monovalent condensed aromatic hydrocarbon group having 2 to 10 aromatic rings, a monovalent linear hydrocarbon group having 1 to 6 carbon atoms, a monovalent branched hydrocarbon group having 2 to 10 carbon atoms, or a hydroxyl group. Y₁ represents a divalent alcohol residue, Z₁ represents a divalent carboxylic acid residue, m represents an integer of from 1 to 5, and preferably an integer of 1, and p represents an integer of from 5 to 5000. B and B′ indicate the groups represented by —O—(Y₁—O)ₘ—H, or —O—(Y₁—O)ₘ—CO-Z₁-CO—OR₂ (wherein Y₁, Z₁, and m represent the same components as the above, and R₂ represents a hydrogen atom, an alkyl group, a substituted or unsubstituted aryl group, or a substituted or unsubstituted aralkyl group).

Y₁ (divalent alcohol residue) and Z₁ (divalent carboxylic acid residue) are formed through the polymerization of, for example, the charge-transporting monomers represented by the following Formula (VI-1) and Formula (VI-2) by, for example, the below-described method.

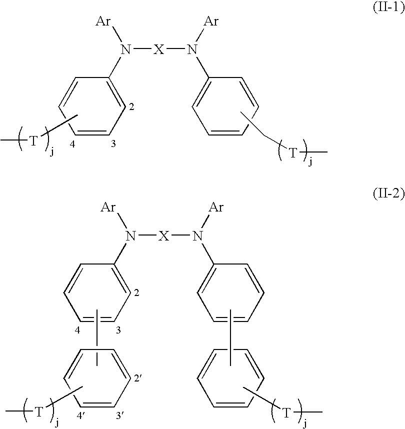

In Formula (II-1) and Formula (II-2), Ar represents a substituted or unsubstituted phenyl group, a substituted or unsubstituted monovalent polynuclear aromatic hydrocarbon having 2 to 10 aromatic rings, a substituted or unsubstituted monovalent condensed aromatic hydrocarbon having 2 to 10 aromatic rings, or a substituted or unsubstituted monovalent aromatic heterocycle, j represents an integer of 0 or 1, and preferably an integer of 1, and T represents a divalent linear hydrocarbon group having 1 to 6 carbon atoms or a divalent branched hydrocarbon group having 2 to 10 carbon atoms, and X represents a group represented by Formula (III).

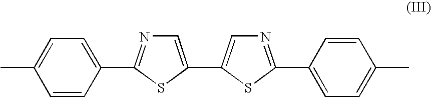

The charge-transporting polyester in the exemplary embodiment has a thiazole ring linked to a phenylene group in the molecular structure thereof, which decreases the ionizing potential, and facilitates charge injection from the electrode. In addition, the polyester structure improves adhesiveness with the substrate to facilitate charge injection. In particular, the polyester structure containing the thiazole ring exhibits excellent solubility and compatibility with a solvent or resin. Accordingly, the organic electroluminescent element in the exemplary embodiment includes at least one organic compound layer containing the charge-transporting polyester thereby providing sufficient luminance, high luminescence efficiency, and a long life. In addition, the use of the charge-transporting polyester allows the increase of the area and easy production of the organic electroluminescent element.

When the charge-transporting polyester has the below-described structure, it has either hole-transporting or electron-transporting properties, and thus is useful for making any layer such as a hole-transporting layer, a light-emitting layer or an electron-transporting layer, according to the intended use. In addition, the charge-transporting polyester in the exemplary embodiment has a relatively high glass transition temperature, and a high carrier mobility.

In the exemplary embodiment, “charge-transporting polyester” refers to a semiconductor polyester which exhibit electrical conductivity via p-type or n-type carriers.

(Charge-Transporting Polyester)

The charge-transporting polyester in the exemplary embodiment is further described below. In the first place, the characteristic structure of the charge-transporting polyester, the A₁ structure in Formula (I-1) and Formula (I-2) is described.

In Formula (II-1) and Formula (II-2), Ar represents a substituted or unsubstituted phenyl group, a substituted or unsubstituted monovalent polynuclear aromatic hydrocarbon having 2 to 10 aromatic rings, a substituted or unsubstituted monovalent condensed aromatic hydrocarbon having 2 to 10 aromatic rings, or a substituted or unsubstituted monovalent aromatic heterocycle. In Formula (II-1) and Formula (II-2), the two Ars may be the same or different from each other, and is preferably the same from the viewpoint of easiness of production.

The number of aromatic rings constituting the polynuclear aromatic hydrocarbon group or the condensed aromatic hydrocarbon group selected as a structure for Ar in Formula (II-1) and Formula (II-2) may be preferably from 2 to 5, but in the condensed aromatic hydrocarbon group, the number of aromatic rings may be preferably from 2 to 4.

In the present exemplary embodiment, a specific definition for the terms “polynuclear aromatic hydrocarbon”, and “condensed aromatic hydrocarbon”, are given below.

That is, the “polynuclear aromatic hydrocarbon” is a hydrocarbon containing two or more aromatic rings which consist of carbon and hydrogen atoms and which are bound to each other via a carbon-carbon bond. Specific examples thereof include biphenyl and terphenyl.

The “condensed aromatic hydrocarbon” is a hydrocarbon compound having two or more aromatic rings consisting of carbon and hydrogen atoms wherein there are a pair of vicinal carbon atoms bonded to each other that are shared by aromatic rings. Specific examples thereof include naphthalene, anthracene, pyrene, phenanthrene, perylene, and fluorene.

The “aromatic heterocycle” selected as a structure for Ar in Formula (II-1) and Formula (II-2), represents an aromatic ring also containing one or more other elements than carbon and hydrogen. In the heterocycle, the number (Nr) of the atoms constituting the cyclic skeleton thereof may be at least anyone of 5 and 6. The kind and number of other atoms (heteroatoms) than carbon atoms in the cyclic skeleton are not particularly limited. For example, a sulfur atom, a nitrogen atom, an oxygen atom or the like may be preferably used as the heteroatom in the aromatic heterocycle. The cyclic skeleton may contain two or more kinds of heteroatoms and/or two or more heteroatoms. In particular, thiophene, pyrrole, furan or a heterocycle obtained by substituting the carbon atom at the 3- or 4-position of any of the above compounds with a nitrogen atom may be used as a heterocycle having a 5-memberred ring structure, and pyridine may be used as a heterocycle having a 6-memberred ring structure.

The scope of the aromatic heterocycle encompasses a heterocycles substituted by an aromatic ring and an aromatic ring substituted by a heterocycle. The heterocycle and the aromatic may include the heterocycle and the aromatic respectively described above. Each of these may be conjugated entirely or partially, but is preferably conjugated entirely, from the point of charge-transporting property and luminous efficiency.

Examples of a substituent that can be substituted on a phenyl group, the polynuclear aromatic hydrocarbon, the condensed aromatic hydrocarbon or the aromatic heterocycle selected as a structure for Ar in Formula (II-1) and Formula (II-2) include a hydrogen atom, an alkyl group, an alkoxy group, an aryl group, an aralkyl group, a substituted amino group, and a halogen atom. The alkyl group may be a group having 1 to 10 carbon atoms, such as a methyl group, an ethyl group, a propyl group or an isopropyl group. The alkoxy group may be a group having 1 to 10 carbon atoms, such as a methoxy group, an ethoxy group, a propoxy group or an isopropoxy group. The aryl group may be a group having 6 to 20 carbon atoms, such as a phenyl group or a toluoyl group. The aralkyl group may be a group having 7 to 20 carbon atoms, such as a benzyl group or a phenethyl group. Examples of a substituent in the substituted amino group include an alkyl group, an aryl group and an aralkyl group, and specific examples thereof are as described above.

In Formula (II-1) and Formula (II-2), T represents a divalent linear hydrocarbon group having 1 to 6 carbon atoms or a divalent branched hydrocarbon group having 2 to 10 carbon atoms, and may be selected from a divalent linear hydrocarbon group having 2 to 6 carbon atoms and a divalent branched hydrocarbon group having 3 to 7 carbon atoms. Among these groups, the following divalent hydrocarbon groups are particularly preferable.

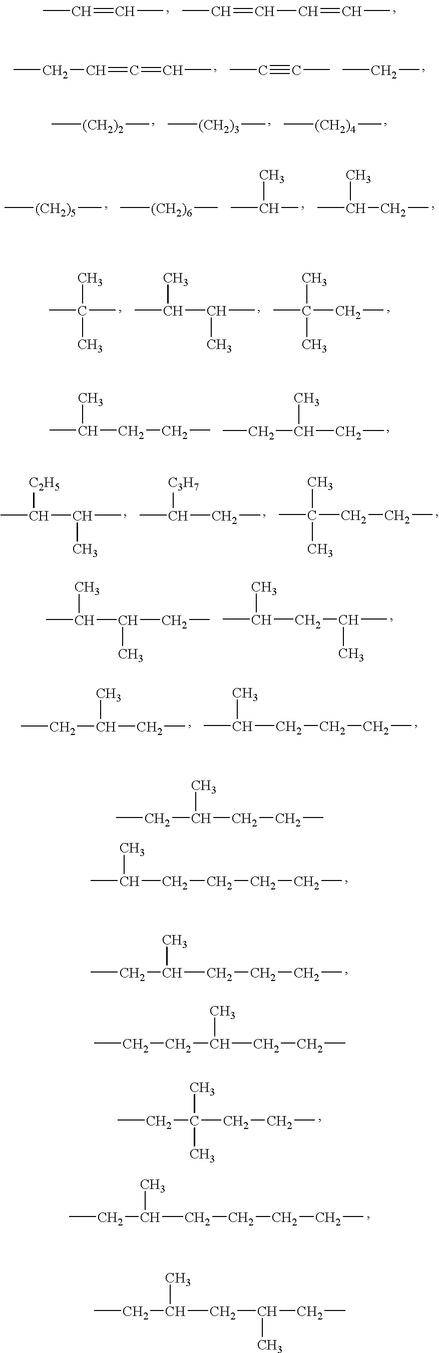

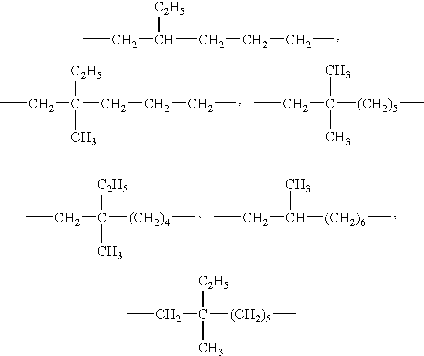

The at least one structure selected from the structures represented by Formula (II-1) and Formula (II-2) described above is A₁ in the charge-transporting polyester represented by Formula (I-1) and Formula (I-2).

The plural A₁s in the charge-transporting polyester represented by Formula (I-1) and Formula (I-2) may have the same structure or different structures.

In Formula (I-1) and Formula (I-2) (including B and B′), Y₁ represents a divalent alcohol residue and Z₁ represents a divalent carboxylic acid residue. Specific examples of the Y₁ and Z₁ include the groups represented by the following Formulae (IV-1) to (IV-6).

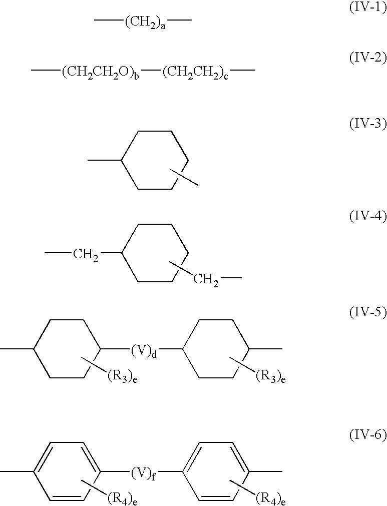

In Formulae (IV-1) to (IV-6), R₃ and R₄ each represent a hydrogen atom, a substituted or unsubstituted alkyl group having 1 to 4 carbon atoms, a substituted or unsubstituted alkoxy group having 1 to 4 carbon atoms, a substituted or unsubstituted phenyl group, a substituted or unsubstituted aralkyl group, or a halogen atom, a, b and c each independently represent an integer of from 1 to 10 respectively, e represents an integer of from 0 to 2, d and f each represent 0 or 1, and V represents the group represented by any one of the following Formulae (V-1) to (V-12).

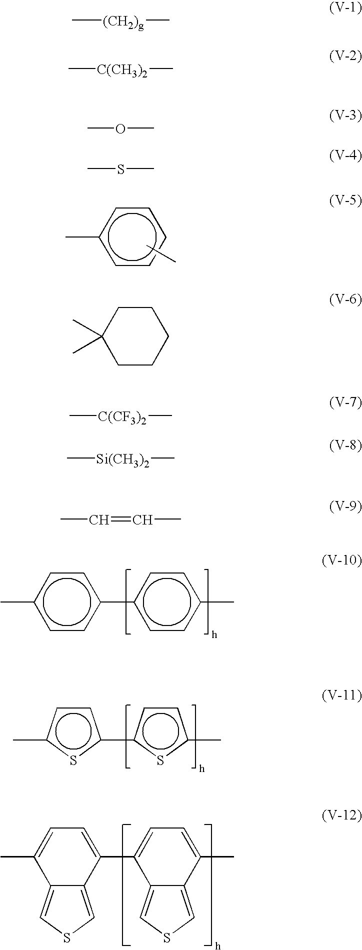

In Formulae (V-1), (V-10), (V-11), and (V-12), g represents an integer of from 1 to 20 respectively, and h represents an integer of from 0 to 10.

In Formula (I-1) and Formula (I-2), m represents an integer of 1 to 6, and p represents an integer of 5 to 5,000 and is preferably an integer of from 10 to 1000. In the exemplary embodiment, the weight-average molecular weight Mw of the charge-transporting polyester may be preferably in the range of 5,000 to 300,000 and particularly in the range of 10,000 to 150,000. The weight-average molecular weight Mw may be determined by the following method. That is, the weight-average molecular weight Mw is determined by preparing a THF solution of 1.0% by weight of the charge-transporting polyester and then analyzing the solution by gel permeation chromatography (GPC) in a differential refractometer (RI) while using styrene polymers as the standard sample.

The glass transition point (Tg) of the charge-transporting polyester may be preferably 50° C. or more and 300° C. or less, and more preferably 90° C. or more and 250° C. or less. The glass transition point is determined with a differential scanning calorimeter with α-alumina (α-Al₂O₃) as the reference by heating the sample to increase its temperature until it becomes rubbery, then rapidly cooling it in liquid nitrogen, and heating it again at an increasing temperature rate of 10° C./min. during which the glass transition point is measured.

The charge-transporting polyesters represented by Formula (I-1) and Formula (I-2) are synthesized through the polymerization of, for example, the charge-transporting monomer represented by the following Formula (VI-1) and Formula (VI-2), by, for example, a known method described in Jikken Kagaku Koza, the 4th edition, vol. 28 (edited by The Chemical Society of Japan, Maruzen Co., Ltd., 1992).

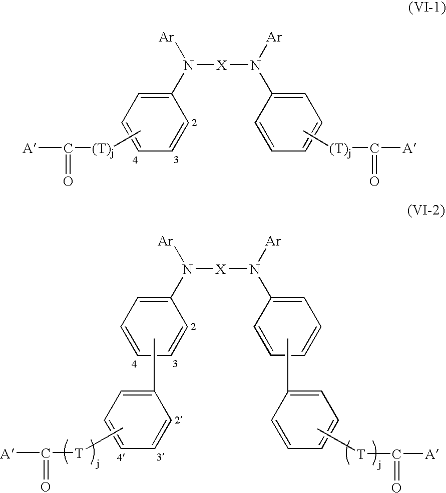

In Formula (VI-1) and Formula (VI-2), Ar, X, T, and j are the same as Ar, X, T, j in Formula (II-1) and Formula (II-2). A′ represents a hydroxyl group, a halogen atom, or —O—R₅ (R₅ represents a substituted or unsubstituted alkyl group, a substituted or unsubstituted aryl group, or a substituted or unsubstituted aralkyl group).

Specific examples of the structure represented by Formula (VI-1) are listed in Tables 1 to 5. In the tables, regarding the specific examples of the charge-transporting monomer indicated with compound numbers, for example, the specific example indicated with a number 5 is referred to as “monomer compound (5)”.

TABLE 1

| *St | Ar | *B.P. | j | T | A′ |
|---|---|---|---|---|---|
| 1 | 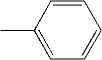 | 3 | 0 | — | OCH₃ |
| 2 | 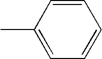 | 3 | 1 | —CH₂CH₂— | OCH₃ |
| 3 | 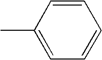 | 4 | 0 | — | OCH₃ |
| 4 | 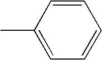 | 4 | 1 | —CH₂— | OCH₃ |
| 5 | 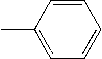 | 4 | 1 | —CH₂CH₂— | OCH₃ |
| 6 | 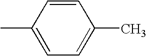 | 4 | 1 | 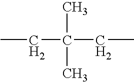 | OCH₃ |
| 7 | 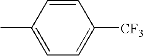 | 4 | 1 | —CH₂CH₂— | OCH₃ |
| 8 | 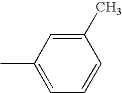 | 3 | 1 | —CH₂— | OCH₂CH₃ |
| 9 | 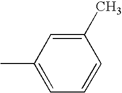 | 4 | 1 | —CH₂— | OCH₃ |
| 10 | 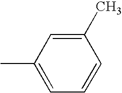 | 4 | 1 | —CH₂CH₂— | OCH₃ |
| 11 | 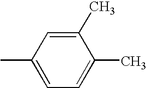 | 4 | 1 | —CH₂CH₂— | OCH₃ |
| 12 | 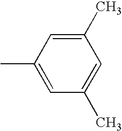 | 4 | 1 | —CH₂CH₂— | OCH₃ |
| 13 | 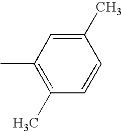 | 4 | 1 | —CH₂CH₂— | OCH₃ |

*St = Structure,
*B.P. = Binding Position.

TABLE 2

| *St | Ar | *B.P. | j | T | A′ |
|---|---|---|---|---|---|
| 14 | 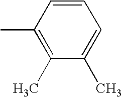 | 4 | 1 | —CH₂CH₂— | OCH₃ |
| 15 | 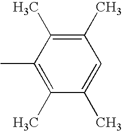 | 4 | 1 | —CH₂CH₂— | OCH₃ |
| 16 | 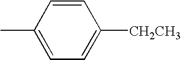 | 4 | 1 | —CH₂CH₂— | OCH₃ |
| 17 | 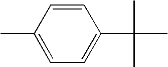 | 4 | 1 | —CH₂CH₂— | OCH₃ |
| 18 | 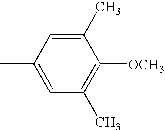 | 4 | 1 | —CH₂CH₂— | OCH₃ |
| 19 | 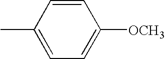 | 4 | 1 | —CH₂CH₂— | OCH₃ |
| 20 | 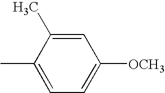 | 4 | 1 | —CH₂CH₂— | OCH₃ |
| 21 | 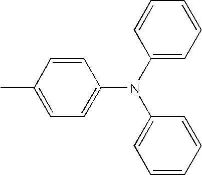 | 4 | 1 | —CH₂CH₂— | OCH₃ |
| 22 | 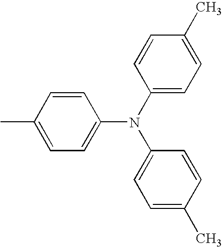 | 4 | 1 | —CH₂CH₂— | OCH₃ |
| 23 | 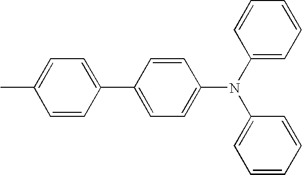 | 4 | 1 | —CH₂CH₂— | OCH₃ |

*St = Structure,
*B.P. = Binding Position.

TABLE 3

| *St | Ar | *B.P. | j | T | A′ |
|---|---|---|---|---|---|
| 24 | 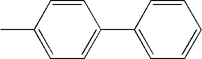 | 4 | 1 | —CH₂CH₂— | OCH₃ |
| 25 | 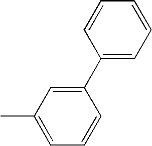 | 4 | 1 | —CH₂CH₂— | OCH₃ |
| 26 | 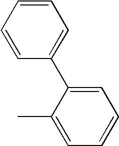 | 4 | 1 | —CH₂CH₂— | OCH₃ |
| 27 | 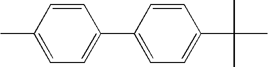 | 4 | 1 | —CH₂CH₂— | OCH₃ |
| 28 | 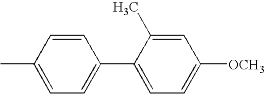 | 4 | 1 | —CH₂CH₂— | OCH₃ |
| 29 | 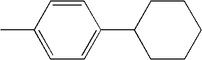 | 4 | 1 | —CH₂CH₂— | OCH₃ |
| 30 | 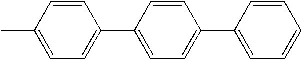 | 4 | 1 | —CH₂CH₂— | OCH₃ |
| 31 | 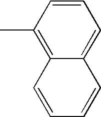 | 4 | 1 | —CH₂CH₂— | OCH₃ |
| 32 | 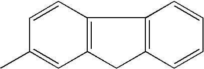 | 4 | 1 | —CH₂— | OCH₃ |
| 33 | 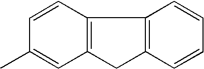 | 4 | 1 | —CH₂CH₂— | OCH₃ |
| 34 | 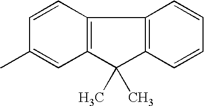 | 4 | 1 | —CH₂— | OCH₃ |

*St = Structure,
*B.P. = Binding Position.

TABLE 4

| *St | Ar | *B.P. | j | T | A′ |
|---|---|---|---|---|---|
| 35 | 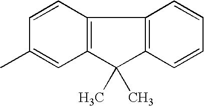 | 4 | 1 | —CH₂CH₂— | OCH₃ |
| 36 | 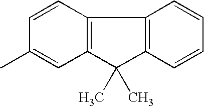 | 4 | 1 | 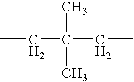 | OCH₃ |
| 37 | 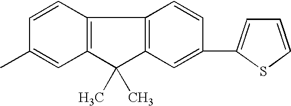 | 4 | 1 | —CH₂CH₂— | OCH₃ |
| 38 | 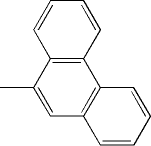 | 4 | 1 | —CH₂CH₂— | OCH₃ |
| 39 | 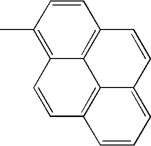 | 4 | 1 | —CH₂CH₂— | OCH₃ |
| 40 | 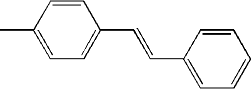 | 4 | 1 | —CH₂CH₂— | OCH₃ |
| 41 | 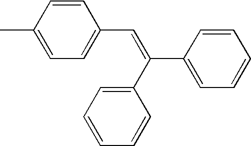 | 4 | 1 | —CH₂CH₂— | OCH₃ |
| 42 | 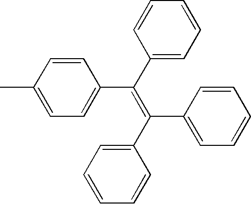 | 4 | 1 | —CH₂CH₂— | OCH₃ |
| 43 | 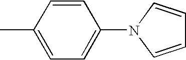 | 4 | 1 | —CH₂CH₂— | OCH₃ |
| 44 | 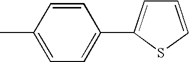 | 4 | 1 | —CH₂CH₂— | OCH₃ |

*St = Structure,
*B.P. = Binding Position.

TABLE 5

| *St | Ar | *B.P. | j | T | A′ |
|---|---|---|---|---|---|
| 45 | 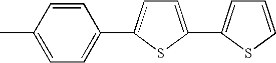 | 4 | 1 | —CH₂CH₂— | OCH₃ |
| 46 | 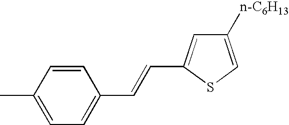 | 4 | 1 | —CH₂CH₂— | OCH₃ |
| 47 | 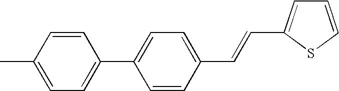 | 3 | 1 | —CH₂CH₂— | OCH₃ |
| 48 | 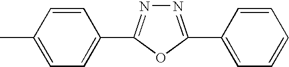 | 4 | 1 | —CH₂CH₂— | OCH₃ |
| 49 | 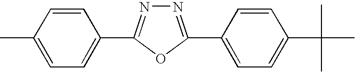 | 4 | 1 | —CH₂CH₂— | OCH₃ |
| 50 | 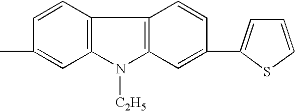 | 4 | 0 | — | OCH₃ |

*St = Structure,
*B.P. = Binding Position.

Specific examples of the structure represented by Formula (VI-2) are listed in Tables 6 to 8.

TABLE 6

| *St | Ar | *B.P. | j | T | A′ |
|---|---|---|---|---|---|
| 51 | 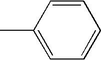 | 4.4′ | 0 | — | OCH₃ |
| 52 | 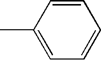 | 4.4′ | 1 | —CH₂— | OCH₃ |
| 53 | 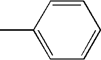 | 4.4′ | 1 | —CH₂CH_{2—} | OCH₃ |
| 54 | 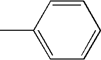 | 4.4′ | 1 | 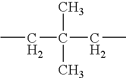 | OCH₃ |
| 55 | 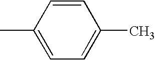 | 4.4′ | 1 | —CH₂— | OCH₃ |
| 56 | 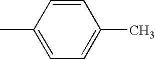 | 4.4′ | 1 | —CH₂CH_{2—} | OCH₃ |
| 57 | 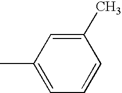 | 4.4′ | 1 | —CH₂CH_{2—} | OCH₃ |
| 58 | 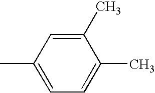 | 4.4′ | 1 | —CH₂CH_{2—} | OCH₃ |
| 59 | 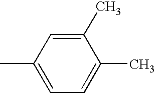 | 4.4′ | 1 | 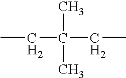 | OCH₃ |
| 60 | 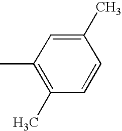 | 4.4′ | 1 | —CH₂CH_{2—} | OCH₃ |
| 61 | 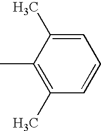 | 4.4′ | 1 | —CH₂CH_{2—} | OCH₃ |
| 62 | 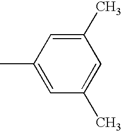 | 4.4′ | 1 | —CH₂CH_{2—} | OCH₃ |

*St = Structure,
*B.P. = Binding Position.

TABLES 7

| *St | Ar | *B.P. | j | T | A′ |
|---|---|---|---|---|---|
| 63 | 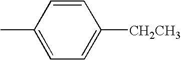 | 4.4′ | 1 | —CH₂CH₂— | OCH₃ |
| 64 | 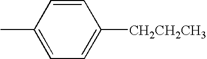 | 4.4′ | 1 | —CH₂CH₂— | OCH₃ |
| 65 | 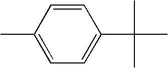 | 4.4′ | 1 | —CH₂CH₂— | OCH₃ |
| 66 | 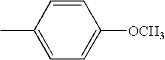 | 4.4′ | 1 | —CH₂CH₂— | OCH₃ |
| 67 | 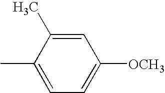 | 4.4′ | 1 | —CH₂CH₂— | OCH₃ |
| 68 | 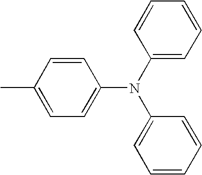 | 4.4′ | 1 | —CH₂CH₂— | OCH₃ |
| 69 | 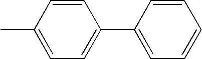 | 4.4′ | 1 | —CH₂CH₂— | OCH₃ |
| 70 | 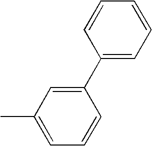 | 4.4′ | 1 | —CH₂CH₂— | OCH₃ |
| 71 | 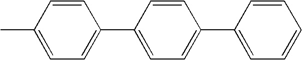 | 4.4′ | 1 | —CH₂— | OCH₃ |
| 72 | 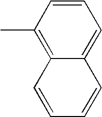 | 4.4′ | 1 | —CH₂CH₂— | OCH₃ |
| 73 | 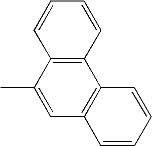 | 4.4′ | 1 | —CH₂— | OCH₃ |
| 74 | 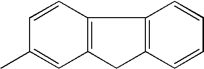 | 4.4′ | 1 | —CH₂CH₂— | OCH₃ |

*St = Structure,
*B.P. = Binding Position.

TABLES 8

| *St | Ar | B.P. | j | T | A′ |
|---|---|---|---|---|---|
| 75 | 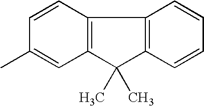 | 4.4′ | 1 | 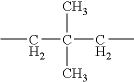 | OCH₃ |
| 76 | 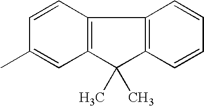 | 4.4′ | 1 | —CH₂CH₂— | OCH₃ |
| 77 | 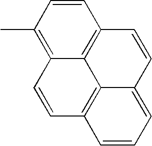 | 4.4′ | 1 | —CH₂CH₂— | OCH₃ |
| 78 | 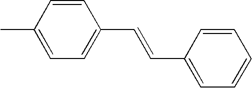 | 4.4′ | 1 | —CH₂CH₂— | OCH₃ |
| 79 | 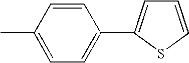 | 4.4′ | 1 | —CH₂— | OCH₃ |
| 80 | 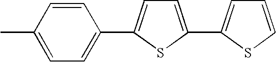 | 4.4′ | 1 | —CH₂CH₂— | OCH₃ |
| 81 | 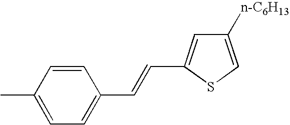 | 4.4′ | 1 | —CH₂CH₂— | OCH₃ |
| 82 | 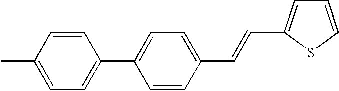 | 4.4′ | 1 | 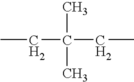 | OCH₃ |
| 83 | 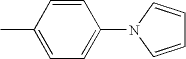 | 4.4′ | 1 | —CH₂CH₂— | OCH₃ |
| 84 | 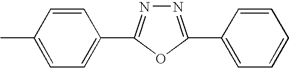 | 4.4′ | 1 | —CH₂CH₂— | OCH₃ |
| 85 | 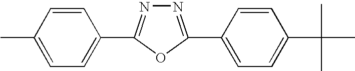 | 4.4′ | 1 | —CH₂CH₂— | OCH₃ |

*St = Structure,
*B.P. = Binding Position.

Wherein in the first place, the method for synthesizing the charge-transporting monomers represented by Formula (VI-1) and Formula (VI-2) are described. An example of the method for synthesizing the charge-transporting monomers is described below, but the invention is not limited to the method.

The charge-transporting monomer in the exemplary embodiment is synthesized as follows: triarylamine represented by the following Formula (VII) is formed by, for example, coupling reaction in the presence of a copper catalyst, and halogenated with, for example, N-bromosuccinimide (NBS) or N-chlorosuccinimide (NCS) to form the compound represented by the following Formula (VIII), and then subjected to homocoupling reaction in the presence of a nickel catalyst to obtain the charge-transporting monomer.

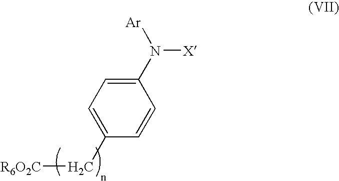

In Formula (VII), Ar is the same as the above-described Ar, X′ represents a substituted or unsubstituted monovalent aromatic group or a substituted or unsubstituted divalent aromatic group containing 1 or more thiazole rings, R₆ represents a hydrogen atom, an alkyl group, a substituted or unsubstituted aryl group, or a substituted or unsubstituted aralkyl group, and n represents an integer of from 0 to 5.

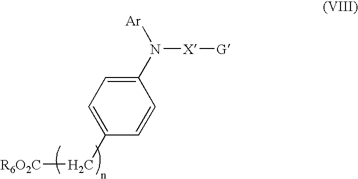

In Formula (VIII), Ar, X′, and R₆ are the same as the above-described, and G′ represents a bromine atom or a chlorine atom, and n represents an integer of from 0 to 5.

The homocoupling reaction is carried out between the compound (VIII) and a nickel complex, triphenylphosphine, and zinc in a solvent. When the halogen atom to be introduced to the compound is a chlorine atom, the halogen atom may be introduced through halogenatation before a triarylamine skeleton is formed through coupling reaction in the presence of a copper catalyst.

In the reaction, the nickel complex may be, for example, nickel chloride, nickel bromide, or nickel acetate, and the usage thereof is from 0.001 to 3 equivalents, preferably from 0.1 to 2 equivalents with respect to 1 equivalent of the compound represented by Formula (VIII). It is preferable that the reaction be carried out in the presence of a reducing agent such as zinc, and the usage thereof is from 0.001 to 3 equivalents, preferably from 0.1 to 2 equivalents with respect to 1 equivalent of the compound represented by Formula (VIII).

The usage of triphenylphosphine is from 0.5 to 3 equivalents, preferably from 0.7 to 2 equivalents with respect to 1 equivalent of the compound represented by Formula (VIII).

The solvent used for the reaction is preferably, for example, dimethylformamide (DMF), dimethylacetamide (DMA), tetrahydrofuran (THF), dimethoxy ethane (DME), or N-methylpyrrolidone (NMP). The usage of the solvent is from 0.1 to 10 equivalents, preferably from 2 to 5 equivalents with respect to 1 equivalent of the compound represented by Formula (VIII). The reaction is carried out in an atmosphere of an inert gas such as nitrogen or argon, at a temperature of 0° C. to 100° C., preferably in a temperature range from room temperature (25° C. or lower, hereinafter the same) to 50° C. under efficient stirring.

After termination of the reaction, the reaction solution is poured into water and the mixture is stirred thoroughly, and, when the reaction product is crystalline, a crude product is collected by suction filtration. When the reaction product is oily, a crude product can be obtained by extraction with a suitable solvent such as ethyl acetate or toluene. The crude product thus obtained is purified by being subjected to column chromatography with silica gel, alumina, activated clay, activated carbon, or the like, or by adding such an adsorbent into the solution and adsorbing undesirable components. When the reaction product is crystalline, it is further purified by recrystallization using a suitable solvent such as hexane, methanol, acetone, ethanol, ethyl acetate, or toluene.

The charge-transporting monomers represented by Formula (VI-1) and Formula (VI-2) obtained described above are polymerized by a known method to obtain the charge-transporting polyesters represented by Formula (I-1) and Formula (I-2).

Specifically, it is preferable that an optional molecule be introduced to the end of the charge-transporting monomers by, for example, the synthesis method described below.

[1] A′ is a hydroxy group

When A′ is a hydroxy group, the monomer is polymerized with an equivalent amount (mass ratio) of a divalent alcohol represented by HO—(Y₁—O)ₘ—H in the presence of an acid catalyst. The Y₁ and m are the same as the Y₁ and m in Formula (I-1) and Formula (I-2).

The acid catalyst may be a common one used for esterification reaction, such as sulfuric acid, toluene sulfonic acid, or trifluoroacetic acid, and the usage thereof is from 1/10,000 to 1/10 parts by weight, preferably from 1/1,000 to 1/50 parts by weight with respect to 1 part by weight of the monomer. In order to remove water generated during the synthesis, the solvent is preferably azeotropic with water. Examples of effective solvent include toluene, chlorobenzene, and 1-chloronaphthalene, and the usage of the solvent is from 1 to 100 parts by weight, preferably from 2 to 50 parts by weight with respect to 1 part by weight of the monomer. The reaction may be carried out at an optional temperature, and is preferably at a boiling point of the solvent thereby removing water generated during the polymerization. After the completion of the reaction, when no solvent is used, the product is dissolved in an appropriate solvent. When a solvent is used, the reaction solution is dropped into an alcohol such as methanol or ethanol, or a poor solvent such as acetone in which the polymer is poorly soluble to precipitate the polymer. The polymer is isolated, thoroughly washed with water or an organic solvent, and dried. As necessary, the reprecipitation treatment including dissolving the polymer in an appropriate organic solvent, and dropping it into a poor solvent to precipitate the polymer may be repeated. The reprecipitation treatment is preferably conducted under efficient stirring with, for example, a mechanical stirrer. The usage of the solvent used for dissolving the polymer during the reprecipitation treatment is from 1 to 100 parts by weight, preferably from 2 to 50 parts by weight with respect to 1 part by weight of the polymer. The usage of the poor solvent is from 1 to 1,000 parts by weight, preferably from 10 to 500 parts by weight with respect to 1 part by weight of the polymer.

[2] A′ is halogen

When A′ is a halogen atom, the monomer is polymerized with an equivalent amount (mass ratio) of a divalent alcohol represented by HO—(Y₁—O)ₘ—H in the presence of an organic basic catalyst such as pyridine or triethylamine. The Y₁ and m are the same as the Y₁ and m in Formula (I-1) and Formula (I-2).

The usage of the organic basic catalyst is from 1 to 10 parts by weight, preferably 2 to 5 parts by weight with respect to 1 part by weight of the monomer. Examples of the effective solvent include methylene chloride, tetrahydrofuran (THF), toluene, chlorobenzene, and 1-chloronaphthalene, and the usage of the solvent is from 1 to 100 parts by weight, preferably from 2 to 50 parts by weight with respect to 1 part by weight of the monomer. The reaction temperature may be optionally established. After the polymerization, reprecipitation and purification are conducted in a manner substantially similar as the above-described [1]. When a highly acidic divalent alcohol such as bisphenol is used, an interfacial polymerization method may be used. That is, water is added to a divalent alcohol, and an equivalent amount (mass ratio) of a base is dissolved therein, and a monomer solution in an equivalent amount to the divalent alcohol is added under vigorously stirring to conduct polymerization. At that time, the usage of water is from 1 to 1,000 parts by weight, preferably from 2 to 500 parts by weight with respect to 1 part by weight of the divalent alcohol. Examples of the effective solvent for dissolving the monomer include methylene chloride, dichloroethane, trichloroethane, toluene, chlorobenzene, and 1-chloronaphthalene. The reaction temperature may be optionally established. In order to accelerate the reaction, it is effective to use a phase transfer catalyst such as an ammonium salt or a sulfonium salt. The usage of the phase transfer catalyst is from 0.1 to 10 parts by weight, preferably from 0.2 to 5 parts by weight with respect to 1 part by weight of the monomer.

[3] A′ is —O—R₅

When A′ is —O—R₅, an excessive amount of a divalent alcohol represented by the HO—(Y₁—O)ₘ—H is added to the monomer, and heated to achieve the synthesis through interesterification in the presence of an inorganic acid such as sulfuric acid or phosphoric acid, an acetate or carbonate of titanium alkoxide, calcium, or cobalt, or zinc oxide or other oxide as the catalyst. The Y₁ and m are the same as Y₁ and m in Formula (I-1) and Formula (I-2).

The usage of the divalent alcohol is from 2 to 100 parts by weight, preferably from 3 to 50 parts by weight with respect to 1 part by weight of the monomer. The usage of the catalyst is from 1/1,000 to 1 part by weight, preferably from 1/100 to 1/2 parts by weight with respect to 1 part by weight of the monomer. The reaction is conducted at a temperature from 200° C. to 300° C. After the completion of interesterification from the group —O—R₅ to the group HO—(Y₁—O)ₘ—H, the reaction is preferably conducted under reduced pressure thereby accelerating the polymerization reaction through the desorption of the group HO—(Y₁—O)ₘ—H. Alternatively, the reaction may be conducted in a high boiling point solvent azeotropic with the group HO—(Y₁—O)ₘ—H, such as 1-chloronaphthalene, while the group HO—(Y₁—O)ₘ—H is removed by azeotropic distillation under reduced pressure.

More specifically, the charge-transporting polyester represented by Formula (I-1) and Formula (I-2) are synthesized as follows. In the respective cases of the [1] to [3], an excessive amount of a divalent alcohol is added to cause reaction thereby forming the compound represented by the following Formula (IX-1) or Formula (IX-2). Subsequently, the compound is used as the monomer and allowed to react with, for example, a divalent carboxylic acid or a divalent carboxylic acid halide according to the method described in [2], whereby a polymer is obtained.

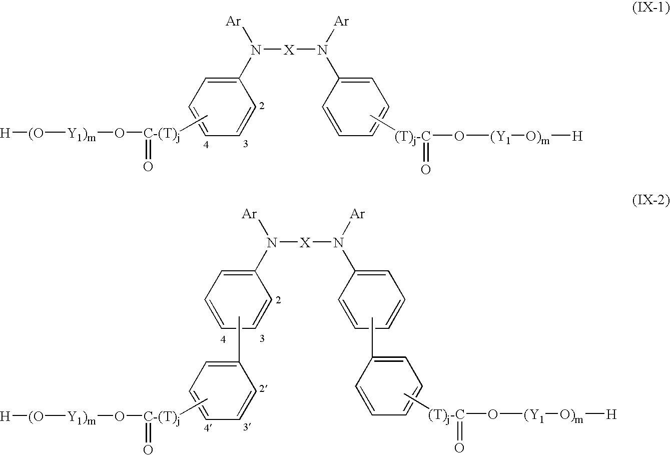

In Formula (IX-1) and Formula (IX-2), Ar, X, T, and j are the same as the Ar, X, T, and j in Formula (II-1) and Formula (II-2), and Y₁ and m are the same as the Y₁ and m in Formula (I-1) and Formula (I-2).

Among the synthesis methods of [1] to [3], the method [1] is particularly preferably for synthesizing the charge-transporting polyester in the exemplary embodiment.

Specific examples of the charge-transporting polyesters represented by Formula (I-1) and Formula (I-2) are listed in Tables 9 and 10, but the charge-transporting polyesters in the exemplary embodiment are not limited to these specific examples. In the following tables, the number listed in the column of A₁ in the monomer section corresponds to the number of the specific examples of the structures represented by Formula (II-1) and Formula (II-2) (the number of charge-transporting monomers listed in Tables 1 to 8). When the Z₁ section is “-”, the compound represents a specific example of the charge-transporting polyester represented by Formula (I-1), and others represent the specific examples of the charge-transporting polyester represented by Formula (I-2).

In the following tables, regarding the specific examples of the charge-transporting polyester indicated with the compound numbers, for example, the specific example indicated with a number 15 is referred to as “exemplary compound (15)”.

TABLE 9

| | Monomer | | | | | |
|---|---|---|---|---|---|---|
| *C No. | A₁ | Ratio | Y₁ | Z₁ | m | p |
| (1) | 2 | — | —CH₂CH₂— | — | 1 | 37 |
| (2) | 4 | — | —CH₂CH₂— | — | 1 | 54 |
| (3) | 5 | — | —CH₂CH₂— | — | 1 | 57 |
| (4) | 6 | — | —CH₂CH₂— | 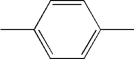 | 1 | 39 |
| (5) | 8 | — | —CH₂CH₂— | — | 1 | 25 |
| (6) | 9 | — | 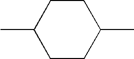 | 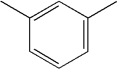 | 2 | 54 |
| (7) | 10 | — | —CH₂CH₂— | — | 1 | 56 |
| (8) | 12 | — | 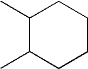 | —(CH₂)₄— | 1 | 64 |
| (9) | 14 | — | 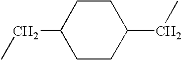 | — | 1 | 48 |
| (10) | 15 | — | —CH₂CH₂— | — | 1 | 46 |
| (11) | 17 | — | —CH₂CH₂— | — | 1 | 51 |
| (12) | 18 | — | —CH₂CH₂— | — | 1 | 48 |
| (13) | 21 | — | —CH₂CH₂— | — | 1 | 24 |
| (14) | 24 | — | —CH₂CH₂— | — | 1 | 32 |
| (15) | 25 | — | —CH₂CH₂— | — | 1 | 44 |
| (16) | 26 | — | —CH₂CH₂— | — | 1 | 47 |
| (17) | 31 | — | —CH₂CH₂— | 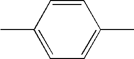 | 2 | 39 |
| (18) | 33 | — | —CH₂CH₂— | —(CH₂)₄— | 1 | 45 |
| (19) | 34 | — | 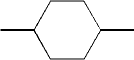 | — | 1 | 68 |
| (20) | 35 | — | —(CH₂)₄— | 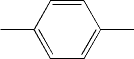 | 2 | 49 |
| (21) | 37 | — | 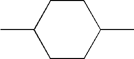 | — | 1 | 55 |
| (22) | 38 | — | —CH₂CH₂— | — | 1 | 34 |
| (23) | 39 | — | 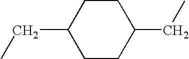 | 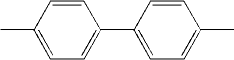 | 1 | 21 |
| (24) | 41 | — | —CH₂CH₂— | — | 1 | 25 |

*C No. = Compound number.

TABLE 10

| | Monomer | | | | | |
|---|---|---|---|---|---|---|
| *C No. | A₁ | Ratio | Y₁ | Z₁ | m | p |
| (25) | 43 | — | —CH₂CH₂— | — | 1 | 35 |
| (26) | 45 | — | —CH₂CH₂— | — | 1 | 25 |
| (27) | 46 | — | 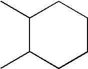 | — | 1 | 35 |
| (28) | 48 | — | 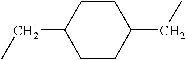 | 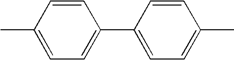 | 1 | 45 |
| (29) | 53 | — | —CH₂CH₂— | — | 1 | 23 |
| (30) | 56 | — | —CH₂CH₂— | — | 1 | 31 |
| (31) | 57 | — | —CH₂CH₂— | — | 1 | 28 |
| (32) | 59 | — | —CH₂CH₂— | — | 1 | 19 |
| (33) | 65 | — | —CH₂CH₂— | — | 1 | 24 |
| (34) | 66 | — | —CH₂CH₂— | — | 1 | 36 |
| (35) | 68 | — | —CH₂CH₂— | — | 1 | 37 |
| (36) | 72 | — | —CH₂CH₂— | — | 1 | 45 |
| (37) | 76 | — | —CH₂CH₂— | — | 1 | 26 |
| (38) | 77 | — | —CH₂CH₂— | — | 1 | 32 |
| (39) | 79 | — | —CH₂CH₂— | — | 1 | 23 |
| (40) | 83 | — | —CH₂CH₂— | — | 1 | 25 |
| (41) | 2/8 | 1/1 | —CH₂CH₂— | — | 1 | 45 |
| (42) | 2/10 | 1/1 | —CH₂CH₂— | — | 1 | 24 |
| (43) | 2/18 | 1/1 | —CH₂CH₂— | — | 2 | 15 |
| (44) | 2/21 | 1/1 | —CH₂CH₂— | — | 1 | 15 |
| (45) | 2/37 | 1/1 | —CH₂CH₂— | 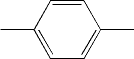 | 1 | 45 |
| (46) | 2/44 | 1/2 | —CH₂CH₂— | — | 1 | 15 |
| (47) | 2/45 | 2/1 | —CH₂CH₂— | — | 1 | 45 |

*C No. = Compound number.

The structure of the organic luminescence element in the exemplary embodiment will now be described in detail.

The layer structure of the organic electroluminescent element in the exemplary embodiment is not particularly limited insofar as it includes a pair of electrodes at least one of which is transparent or semitransparent, and one or more organic compound layers disposed between the pair of electrodes, wherein at least one of the organic compound layers includes at least one charge-transporting polyester described above.

In the organic electroluminescent element in the exemplary embodiment wherein the number of the organic compound layers is 1, the organic compound layer refers to a light-emitting layer having a charge transporting ability, and the light-emitting layer contains the above charge-transporting polyester. When there are plural organic layers (that is, in the case of a function separation type where the respective layers have different functions), at least one of the layers is a light-emitting layer, and this light-emitting layer may be a light-emitting layer having a charge transporting ability. In this case, specific examples of the layer structure including the light-emitting layer or the light-emitting layer having a charge transporting ability, and one or more other layers include the following (1) to (3):

(1) A layer structure having a light-emitting layer and at least anyone layer selected from an electron-transporting layer and an electron injection layer.

(2) A layer structure having at least anyone layer selected from a hole-transporting layer and a hole injection layer, a light-emitting layer, and at least anyone layer selected from an electron-transporting layer and an electron injection layer.

(3) A layer structure having at least anyone layer selected from a hole-transporting layer and a hole injection layer, and a light-emitting layer.

The other layers than the light-emitting layer (or the light-emitting layer having a charge transporting ability) in these layer structures (1) to (3) have a function as either a charge-transporting layer or a charge injection layer. In any of the layer structures (1) to (3), there is a layer containing the charge-transporting polyester.

In the organic electroluminescent element in the exemplary embodiment, the light-emitting layer, the hole-transporting layer, the hole injection layer, the electron-transporting layer, and the electron injection layer may further contain a charge-transporting compound (hole-transporting material, electron-transporting material) other than the charge-transporting polyester. Details of this charge-transporting compound are described later.

The present invention is further described below with reference to the following drawings, but the organic electroluminescent element in the exemplary embodiment is not limited to them.

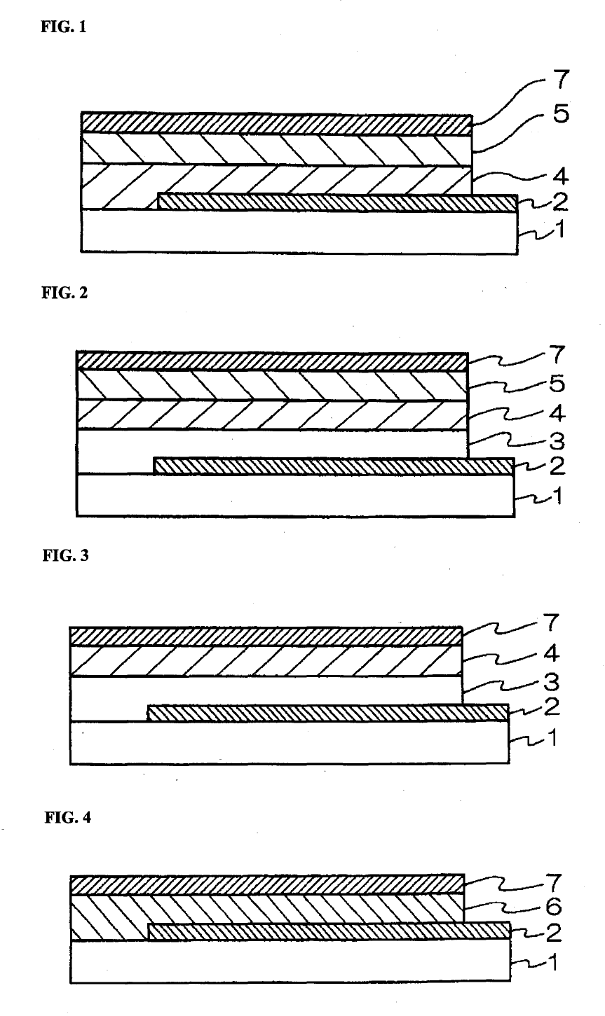

FIGS. 1 to 4 are schematic cross sectional views for illustrating the layer structure of the organic electroluminescent element in the exemplary embodiment. FIGS. 1, 2, and 3 show examples including plural organic compound layers, and FIG. 4 shows an example including one organic compound layer. In FIGS. 1 to 4, members having the same function are indicated with the same reference numerals.

An organic electroluminescent element shown in FIG. 1 has a transparent electrode 2, a light-emitting layer 4, at least one layer 5 selected from an electron-transporting layer and an electron injection layer, and a back electrode 7, disposed in this order on a transparent insulating substrate 1, and corresponds to the layer structure (1). However, when the layer shown by the reference character 5 consists of an electron-transporting layer and an electron injection layer, the electron-transporting layer, the electron injection layer and the back electrode 7 are layered in this order at the back electrode 7 side of the light-emitting layer 4.

An organic electroluminescent element shown in FIG. 2 has a transparent electrode 2, at least one layer 3 selected from a hole-transporting layer and a hole injection layer, a light-emitting layer 4, at least one layer 5 selected from an electron-transporting layer and an electron injection layer, and a back electrode 7, disposed in this order on a transparent insulating substrate 1, and corresponds to the layer structure (2). However, when the layer shown by the reference character 3 consists of a hole-transporting layer and a hole injection layer, the hole injection layer, the hole-transporting layer and the light-emitting layer 4 are layered in this order at the back electrode 7 side of the transparent electrode 2. When the layer shown by the reference character 5 consists of an electron-transporting layer and an electron injection layer, the electron-transporting layer, the electron injection layer and the back electrode 7 are layered in this order at the back electrode 7 side of the light-emitting layer 4.

An organic electroluminescent element shown in FIG. 3 has a transparent electrode 2, at least one layer 3 selected from a hole-transporting layer and a hole injection layer, a light-emitting layer 4 and a back electrode 7, disposed in this order on a transparent insulating substrate 1, and corresponds to the layer structure (3). However, when the layer shown by the reference character 3 consists of a hole-transporting layer and a hole injection layer, the hole injection layer, the hole-transporting layer and the light-emitting layer 4 are layered in this order at the back electrode 7 side of the transparent electrode 2.

An organic electroluminescent element shown in FIG. 4 has a transparent electrode 2, a light-emitting layer 6 with a charge transporting ability and a back electrode 7, disposed in this order on a transparent insulating substrate 1.

It is possible to adopt, for example, a top emission structure, a transmission structure using transparent electrodes for both of the anode and the cathode, in which case the structure may be a structure in which plural layer structures selected from those shown in FIGS. 1 to 4 are stacked.

Hereinafter, more specific descriptions are given.

The charge-transporting polyester in the exemplary embodiment may have either hole-transporting or electron-transporting properties, according to the intended function of the organic compound layer included therein.

For example, when the organic electroluminescent element has the layer structure shown in FIG. 1, the charge-transporting polyester may be contained in the light-emitting layer 4 or the at least one layer 5 selected from an electron-transporting layer and an electron injection layer, both of which serve as the light-emitting layer 4 and the at least one layer 5 selected from an electron-transporting layer and an electron injection layer. When the organic electroluminescent element has the layer structure shown in FIG. 2, the charge-transporting polyester may be contained in the at least one layer 3 selected from a hole-transporting layer and a hole injection layer, the light-emitting layer 4, or the at least one layer 5 selected from an electron-transporting layer and an electron injection layer, all of which serve as the at least one layer 3 selected from a hole-transporting layer and a hole injection layer, the light-emitting layer 4, or the at least one layer 5 selected from an electron-transporting layer and an electron injection layer. When the organic electroluminescent element has the layer structure shown in FIG. 3, the charge-transporting polyester may be contained in the at least one layer 3 selected from a hole-transporting layer and a hole injection layer, or the light-emitting layer 4, both of which serve as the at least one layer 3 selected from a hole-transporting layer and a hole injection layer, and the light-emitting layer 4. When the organic electroluminescent element has the layer structure shown in FIG. 4, the charge-transporting polyester is contained in the light-emitting layer 6 having charge-transporting properties, which serves as the light-emitting layer 6 having charge-transporting properties.

When the organic electroluminescent element has the layer structures shown in any one of FIGS. 1 to 4, the transparent insulating substrate 1 is preferably transparent for transmitting luminescence, and may be, but not limited to, glass or a plastic film. The term “transparent” means that the light transmittance in the visible region is 10% or more. The transmittance is preferably 75% or more. Hereinafter the same shall apply.

The transparent electrode 2 is preferably transparent or translucent for transmitting luminescence in a manner substantially similar as the transparent insulating substrate, and preferably has a work function of 4 eV or more thereby conducting hole injection. The term “translucent” means that the light transmittance in the visible region is 70% or more. The transmittance is preferably 85% or more. Hereinafter the same shall apply.

Specific examples of the transparent electrode 2 include, but not limited to, oxide films such as indium tin oxide (ITO), tin oxide (NESA), indium oxide, and zinc oxide, and evaporated or sputtered gold, platinum, and palladium. The sheet resistance of the electrode is preferably as low as possible, preferably a few hundred Ω/□ or less, and more preferably 100Ω/□ or less. In a manner substantially similar as the transparent insulating substrate, in the visible region, the transparent electrode 2 has a light transmittance of 10% or more, preferably 75% or more.

When the organic electroluminescent element has the layer structure shown in any FIGS. 1 to 3, the electron-transporting layer or the hole-transporting layer may be composed exclusively of the charge-transporting polyester which may have appropriate function (e.g., electron-transporting properties or hole-transporting properties) according to the intended use. Alternatively, for example, in order to adjust the hole mobility, a hole-transporting material other than the charge-transporting polyester may be added at a ratio of 0.1% to 50% by weight with respect to the all materials composing the layer.

Examples of the hole-transporting material include tetraphenylenediamine derivatives, triphenylamine derivatives, carbazole derivatives, stilbene derivatives, spirofluorene derivatives, arylhydrazone derivatives, and porphyrin-based compounds. Among them, tetraphenylenediamine derivatives, spirofluorene derivatives, and triphenylamine derivatives are preferable because they are highly compatible with the charge-transporting polyester.

Similarly, for regulating electron mobility, the electron-transporting material may be mixed and dispersed in the range of 0.1 to 50% by weight with respect to whole materials constituting the layer. Examples of this electron-transporting material include oxadiazole derivatives, nitro-substituted fluorenone derivatives, diphenoquinone derivatives, thiopyran dioxide derivatives, silole derivatives, chelate-type organometallic complexes, polynuclear or condensed aromatic ring compounds, perylene derivatives, triazole derivatives, and fluorenylidene methane derivatives.

When it is necessary to control both of the hole mobility and the electron mobility, both of the hole-transporting material and electron-transporting material may be mixed in the charge-transporting polyester.

For improving film-forming properties and for preventing pinholes, suitable resins (polymers) and/or additives may be added. Specific examples of resins include electroconductive resins such as a polycarbonate resin, a polyester resin, a methacrylic resin, an acrylic resin, a polyvinyl chloride resin, a cellulose resin, a urethane resin, an epoxy resin, a polystyrene resin, a polyvinyl acetate resin, a styrene-butadiene copolymer, a vinylidene chloride-acrylonitrile copolymer, a vinyl chloride-vinyl acetate-maleic anhydride copolymer, a silicone resin, a poly-N-vinylcarbazole resin, a polysilane resin, a polythiophene, and a polypyrrole. As additives, known antioxidants, UV absorbers and plasticizers may be used.

A hole injection layer and/or an electron injection layer may be used in order to improve charge injection properties. Examples of usable hole injection materials include triphenylamine derivatives, phenylenediamine derivatives, phthalocyanine derivatives, indanthrene derivatives, and polyalkylene dioxythiophene derivatives. These derivatives may be mixed with a Lewis acid, sulfonic acid etc. Examples of the electron injection material include metals such as Li, Ca, Ba, Sr, Ag and Au, metal fluorides such as LiF and MgF₂, and metal oxides such as MgO, Al₂O₃ and Li₂O.

If the charge-transporting polyester is used for other purposes than light emitting function, a light-emitting compound is used as a light-emitting material. As the light-emitting material, a compound showing high light-emitting quantum efficiency in a solid state may be used. The light-emitting material may be either a low-molecular-weight compound or a high-molecular-weight compound. In the case of such organic low-molecular-weight compound, suitable examples thereof include chelate organometallic complexes, polynuclear or condensed aromatic ring compounds, perylene derivatives, coumarin derivatives, styrylarylene derivatives, silole derivatives, oxazole derivatives, oxathiazole derivatives, and oxadiazole derivatives. In the case of the high-molecular-weight compound, suitable examples thereof include polyparaphenylene derivatives, polyparaphenylenevinylene derivatives, polythiophene derivatives and polyacetylene derivatives. Suitable specific examples include, but are not limited to, the following light-emitting materials (X-1) to (X-17).

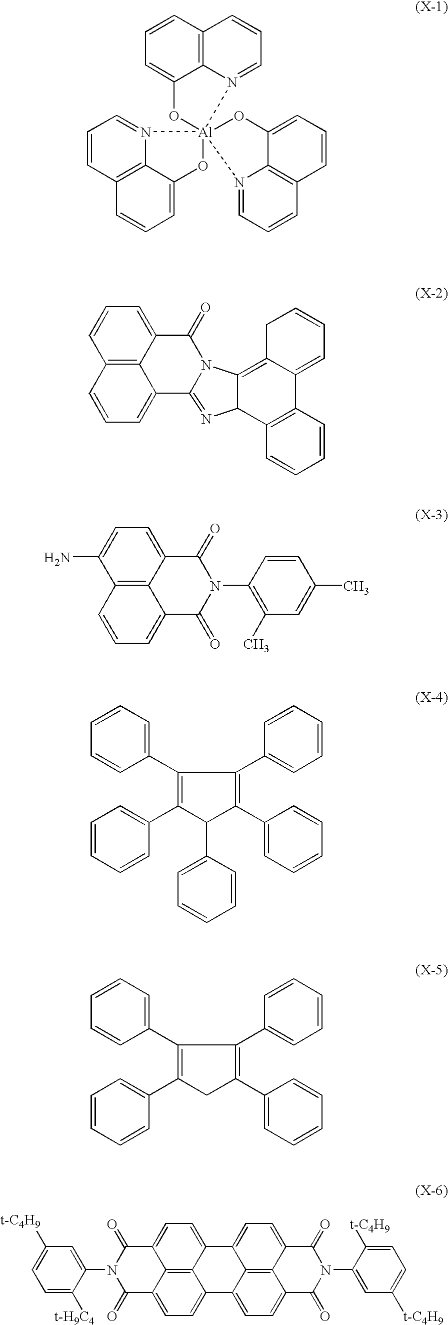

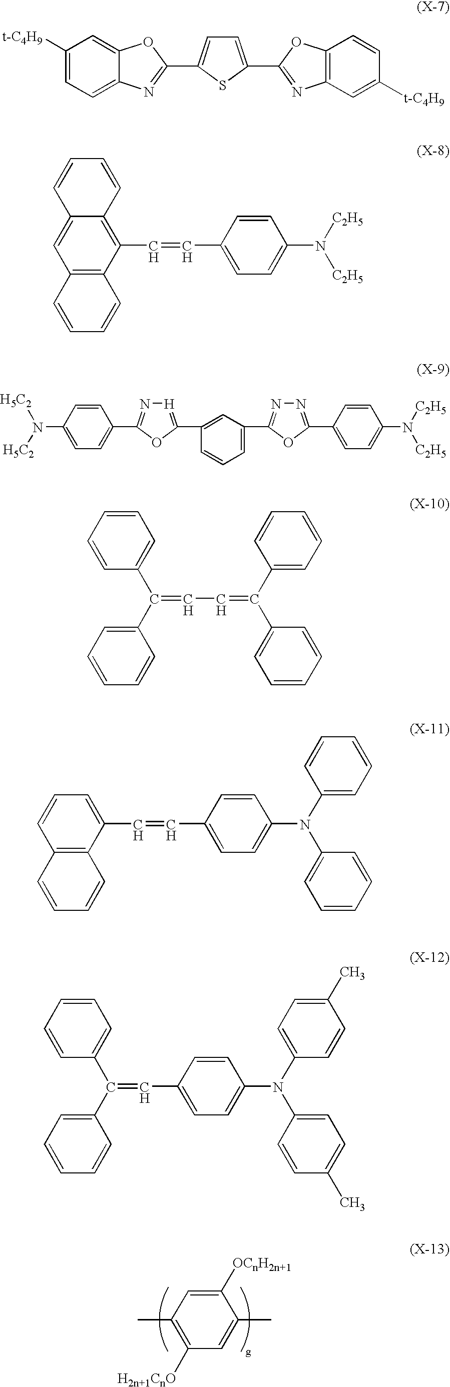

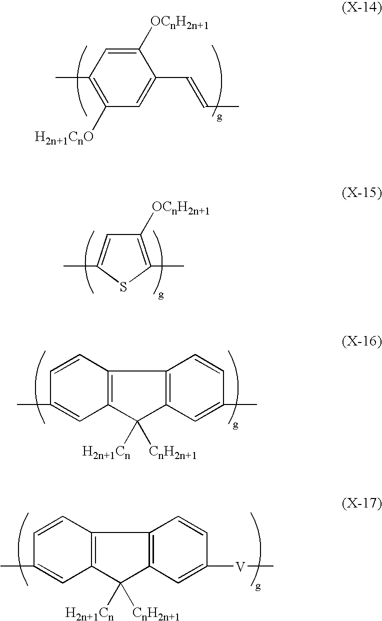

In Formula (X-17), V represents the group represented by any one of Formulae (V-1) to (V-12) above, and n and g each independently represent an integer of 1 or more.

In order to improve the durability or luminescence efficiency of the organic electroluminescent element, the light-emitting material or the charge-transporting polyester may be doped with, as a guest material, a dye compound different from the light-emitting material. The doping ratio of the dye compound is from 0.001% to 40% by weight, preferably from 0.01% to 10% by weight with respect to the objective layer. The dye compound used for the doping is an organic compound which is highly compatible with the light-emitting material, and will not hinder the favorable thin film formation of the light-emitting layer. Preferable examples of the dye compound include coumarin derivatives, 4-dicyanmethylene-2-methyl-6-(4-dimethylaminostyryl)-4H-pyran (DCM) derivatives, quinacridone derivatives, perimidone derivatives, benzopyran derivatives, rhodaminederivatives, benzothio xanthene derivatives, rubrene derivatives, porphyrin derivatives, and metal complex compounds such as those including ruthenium, rhodium, palladium, silver, rhenium, osmium, iridium, platinum, and gold. Preferable specific examples include, but not limited to, the following compounds (XI-1) to (XI-6).

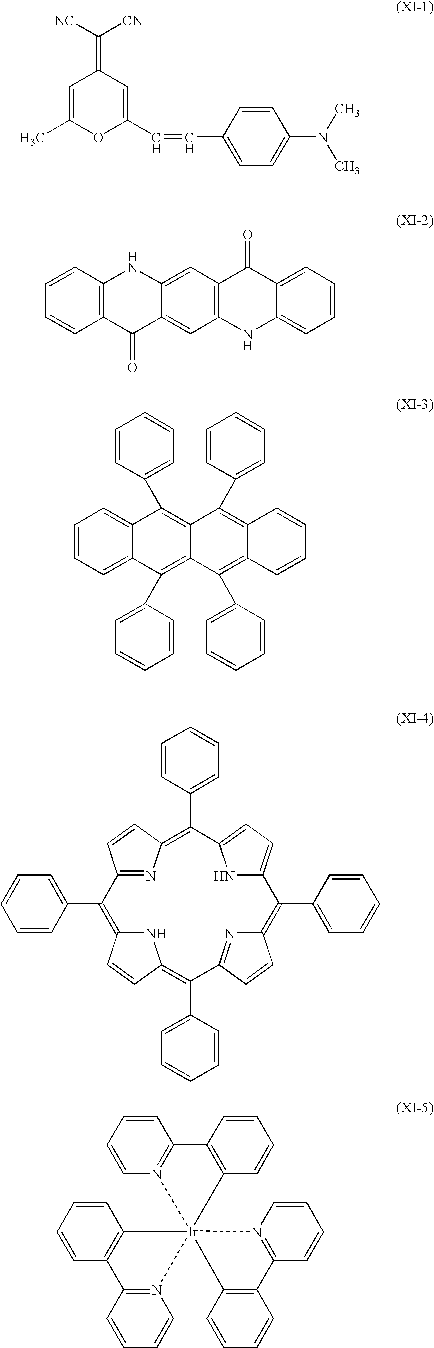

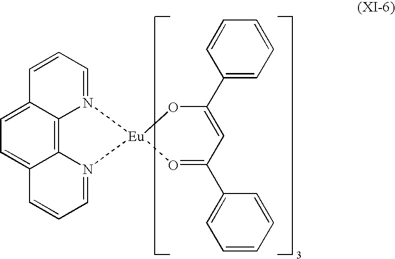

The light-emitting layer 4 may be composed exclusively of the light-emitting material. Alternatively, in order to further improve the electrical properties and light-emitting properties, the charge-transporting polyester may be mixed and dispersed in the light-emitting material in the range of 1% to 50% by weight. Alternatively, a charge-transporting material other than the charge-transporting polyester may be mixed and dispersed in the light-emitting material in the range of 1% to 50% by weight. When the charge-transporting polyester has light-emitting properties, it may be used as a light-emitting material. In this case, in order to further improve the electrical properties and light-emitting properties, the charge-transporting material other than the charge-transporting polyester may be mixed and dispersed in the range of 1% to 50% by weight.

When the organic electroluminescent element has the layer structure shown in FIG. 4, the light-emitting layer 6 having charge-transporting properties is an organic compound layer composed of the charge-transporting polyester having intended function (hole-transporting properties or electron-transporting properties) and a light-emitting material (preferably at least one selected from the light-emitting materials (X-1) to (X-17)) dispersed therein at a ratio of 50% by weight or less. In order to adjust the balance between the holes and electrons injected into the organic electroluminescent element, the charge transport material other than the charge-transporting polyester may be dispersed in the range of 10% to 50% by weight.

When the charge transport material is used for adjusting the electron mobility, examples of the electron-transporting material include oxadiazole derivatives, nitro-substituted fluorenone derivatives, diphenoquinone derivatives, thiopyran dioxide derivatives, and fluorenylidenemethane derivatives.

In the case of the layer structure of each of the organic electroluminescent elements shown in FIGS. 1 to 4, those materials that can be vacuum-deposited and have a lower work function for injection of electrons, such as metals, metal oxides and metal fluorides, may be used in the back electrode 7. Examples of the metals include magnesium, aluminum, gold, silver, indium, lithium, calcium, and alloys thereof. Examples of the metal oxides include lithium oxide, magnesium oxide, aluminum oxide, indium tin oxide, tin oxide, indium oxide, zinc oxide, and indium zinc oxide. Examples of the metal fluorides include lithium fluoride, magnesium fluoride, strontium fluoride, calcium fluoride, and aluminum fluoride.

On the back electrode 7, a protective layer may be provided for avoiding deterioration of the device by moisture or oxygen. Specific examples of materials for the protective layer include metals such as In, Sn, Pb, Au, Cu, Ag and Al, metal oxides such as MgO, SiO₂ and TiO₂, and resins such as polyethylene, polyurea and polyimide. The protective layer can be formed for example by vacuum deposition, sputtering, plasma polymerization, CVD or coating.

The organic electroluminescent element shown in each of FIGS. 1 to 4 may be formed by successively forming, on a transparent electrode 2, individual layers corresponding to the layer structure of the organic electroluminescent element. At least one layer 3 selected from a hole-transporting layer and a hole injection layer, a light-emitting layer 4, and at least one layer 5 selected from an electron-transporting layer and an electron injection layer, or a light-emitting layer 6 having a charge transporting ability may be formed on the transparent electrode 2 by providing the respective materials by a vacuum vapor deposition method or by a spin coating, casting, dipping or inkjet method using a coating liquid obtained by dissolving or dispersing such materials in a suitable organic solvent.

The charge-transporting polyester in the exemplary embodiment has high heat stability and excellent solubility as described above, and thus is preferably included in the organic electroluminescent elements having the structure shown in FIGS. 2 and 4 in consideration of easiness of the formation of respective layers and stability of the elements.

In particular, when the organic electroluminescent element has the structure shown in FIG. 2, which includes the charge-transporting polyester in the exemplary embodiment, the layer structure divides the functions thereby improving the energy efficiency.

The film thickness of the at least one layer 3 selected from a hole-transporting layer and a hole injection layer, light-emitting layer 4, at least one layer 5 selected from an electron-transporting layer and an electron injection layer, and light-emitting layer 6 having charge-transporting properties are preferably 10 μm or less, and particularly preferably 0.001 μm or more and 5 μm or less. These materials (e.g., the non-conjugated polymer, light-emitting material) may be dispersed in the form of molecules, or particles such as microcrystals. When the thin film is formed using a coating solution, the dispersion solvent must be selected in consideration of the dispersibility and solubility of these materials to achieve a state wherein the materials are dispersed in the form of molecules. Examples of the means for dispersing the materials in the form of particles include a ball mill, a sand mill, a paint shaker, an attritor, a homogenizer, and ultrasonic vibration.

When the organic electroluminescent element has the structure shown in FIGS. 1 and 2, the organic electroluminescent element in the exemplary embodiment is obtained by forming the back electrode 7 by, for example, vacuum deposition or sputtering on the at least one layer 5 selected from an electron-transporting layer and an electron injection layer. When the organic electroluminescent element has the structures shown in FIGS. 3 and 4, the organic electroluminescent element in the exemplary embodiment is obtained by forming the back electrode 7 by, for example, vacuum deposition or sputtering on the light-emitting layer 4 and the light-emitting layer 6 having charge-transporting properties, respectively.

<Display Device>

The display device in the exemplary embodiment includes the organic electroluminescent elements in the exemplary embodiment arranged in a matrix configuration and/or a segment configuration. In the exemplary embodiment, when arranging the organic electroluminescent elements in a matrix configuration, the electrodes only may be disposed in the matrix configuration, or the one or more organic compound layers, as well as the electrodes, may be disposed in the matrix configuration. When arranging the organic electroluminescent elements in a segment configuration in the exemplary embodiment, electrodes only may be disposed in the segment configuration, or the one or more organic compound layers, as well as, the electrodes may be disposed in the segment configuration.

The organic one or more compound layers disposed in the matrix or segment shape may be prepared easily by the inkjet method described above. As the method of driving the display device which is structured with the organic electroluminescent elements in a matrix configuration or the organic electroluminescent elements in the segment configuration, techniques conventionally known in the art may be used.

### EXAMPLES

Hereunder is a specific description of exemplary embodiments of the present invention with reference to Examples. However, the present invention is not limited to these Examples.

<Synthesis of Charge-Transporting Polyester>

### Synthesis Example 1

37.5 g of acetoanilide, 96.6 g of methyl 4-iodophenyl propionate, 57.5 g of potassium carbonate, 3.5 g of copper sulfate pentahydrate, and 75 ml of N-tridecane were placed in a three-necked flask, and heated at 230° C. for 20 hours under stirring in a nitrogen gas stream. After the completion of the reaction, 300 ml of ethylene glycol and 23.4 g of potassium hydroxide were added to the flask, and the flask was heated for 3.5 hours under reflux in a nitrogen gas stream. Thereafter, the flask was cooled to room temperature, the content was poured into 1 L of distilled water, and neutralized with hydrochloric acid to precipitate crystals. Subsequently, the crystals were collected by filtration, and washed with water. Subsequently, 500 ml of toluene was added to the crystals, and heated under reflux to remove water by azeotropic distillation. Thereafter, 450 ml of methanol and 3.0 ml of concentrated sulfuric acid were added, and heated for 5 hours under reflux in a nitrogen gas stream. After the completion of the reaction, the organic layer was extracted with toluene, and washed with distilled water. Subsequently, the layer was dried with anhydrous sodium sulfate, then the solvent was removed under reduced pressure, and 57.8 g of “intermediate compound 1” was recrystallized from hexane.

Thereafter, “intermediate compound 2” was synthesized according to the following reaction scheme.

15.0 g of the “intermediate compound 1” obtained above, 15.5 g of 2-(4-bromobenzoyl)-1,3-thiazole, 12.2 g of potassium carbonate, 0.8 g of copper sulfate pentahydrate, and 30 ml of o-dichlorobenzene were placed in a 200-ml flask, and heated for 10 hours under reflux in a nitrogen gas stream. After the completion of the reaction, the flask was cooled to room temperature, and the content was dissolved in 100 ml of toluene. Impurities were removed by filtration, and the filtrate was purified by silica gel column chromatography (toluene/hexane=1:1). As a result of this, 10.5 g of “intermediate compound 2” was obtained.

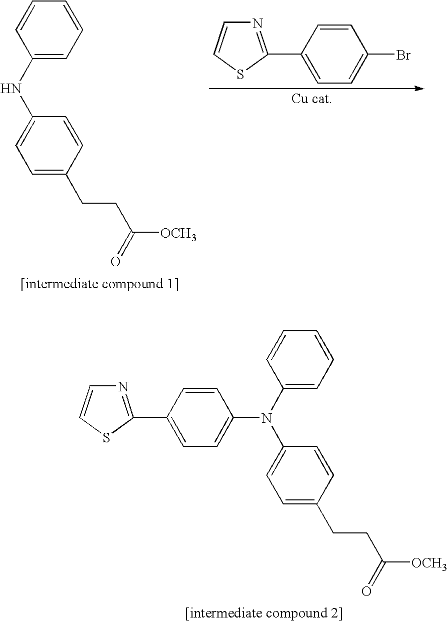

10.0 g of the “intermediate compound 2” obtained above was dissolved in 25 ml of dimethylformamide (DMF), 3.4 g of N-chlorosuccinimide (NCS) was added thereto, and stirred for 4 hours at room temperature in a nitrogen gas stream. After the completion of the reaction, the reaction solution was poured into distilled water to precipitate crystals. The obtained crystals were collected by suction filtration, and washed with distilled water to obtain 6.4 g of the chlorinated compound of the “intermediate compound 2”.

Thereafter, in a nitrogen gas stream, 1.7 g of anhydrous nickel chloride, 14.0 g of triphenylphosphine, and 70 ml of DMF were placed in an eggplant-shaped flask, and heated under stirring. When the reaction solution reached 50° C., 0.9 g of zinc (powder) was added, and heated at 50° C. for 1 hour under stirring. Thereafter, 6.0 g of the chlorinated compound was added, and heated at 50° C. for 0.5 hours under stirring. After the completion of the reaction, the reaction solution was cooled to room temperature, and poured into 500 ml of distilled water, and stirred. Subsequently, the precipitated crystals were collected by suction filtration, and washed with pure water to obtain crystals. The obtained crystals were purified by silica gel column chromatography (hexane/ethyl acetate=1:1) to obtain 8.2 g of the monomer compound (5).

1.0 g of the monomer compound (5), 3.0 g of ethylene glycol, and 0.04 g of tetrabutoxy titanium were placed in a 100-ml three-necked eggplant-shaped flask, and heated at 200° C. for 3 hours under stirring in a nitrogen gas stream. After consumption of the monomer compound (5), the pressure was reduced to 0.5 mmHg, and the flask was heated to 230° C. to continue the reaction for 5 hours while ethylene glycol was removed by evaporation. Thereafter, the flask was cooled to room temperature, and the content was dissolved in 200 ml of tetrahydrofuran. The insoluble matter was filtered through a 0.5-μm polytetrafluoroethylene (PTFE) filter, and the filtrate was dropped into 500 ml of methanol under stirring to precipitate a polymer. The obtained polymer was collected by filtration, washed with methanol, and then dried to obtain 0.8 g of the exemplary compound (3).

The molecular weight of the exemplary compound (3) was measured by gel permeation chromatography (GPC, manufactured by Tosoh Corporation, HLC-8120GPC); the weight average molecular weight (Mw) was 4.7×10⁴ (in terms of styrene), and the p value calculated from the molecular weight of the monomer was about 57.

The glass transition temperature (Tg) measured with a differential scanning calorimeter (manufactured by Seiko Instruments, Inc., Tg/DTA6200) was 135° C.

### Synthesis Example 2

An intermediate compound was synthesized in a manner substantially similar as Synthesis Example 1, except that 3-methylacetoanilide and methyl 3-iodopheny propionate were used in place of acetoanilide and methyl 4-iodophenyl propionate used for the synthesis of the “intermediate compound 1”. The intermediate compound was then subjected to triarylation and chlorination, and the obtained chlorinated compound was subjected to homocoupling reaction to obtain the monomer compound (8).

Subsequently, the monomer compound (8) was polymerized in a manner substantially similar as Synthesis Example 1 to obtain the exemplary compound (5).

The molecular weight of the exemplary compound (5) was measured by gel permeation chromatography (GPC, manufactured by Tosoh Corporation, HLC-8120GPC); the weight average molecular weight (Mw) was 2.1×10⁴ (in terms of styrene), and the p value calculated from the molecular weight of the monomer was about 25.

The glass transition temperature (Tg) measured with a differential scanning calorimeter (manufactured by Seiko Instruments, Inc., Tg/DTA6200) was 115° C.

### Synthesis Example 3

An intermediate compound was synthesized in a manner substantially similar as Synthesis Example 1, except that t-butylacetoanilide was used in place of acetoanilide used for the synthesis of the “intermediate compound 1”. The intermediate compound was then subjected to triarylation and chlorination, and the obtained chlorinated compound was subjected to homocoupling reaction to obtain the monomer compound (17).

Subsequently, the monomer compound (17) was polymerized in a manner substantially similar as Synthesis Example 1 to obtain the exemplary compound (11).

The molecular weight of the exemplary compound (11) was measured by gel permeation chromatography (GPC, manufactured by Tosoh Corporation, HLC-8120GPC); the weight average molecular weight (Mw) was 9.4×10⁴ (in terms of styrene), and the p value calculated from the molecular weight of the monomer was about 51.

The glass transition temperature (Tg) measured with a differential scanning calorimeter (manufactured by Seiko Instruments, Inc., Tg/DTA6200) was 128° C.

### Synthesis Example 4

An intermediate compound was synthesized in a manner substantially similar as Synthesis Example 1, except that 4-bromotriphenylamine and methyl 3-(4-acetylaminophenyl) propionate ester were used in place of 37.5 g of acetoanilide and 96.6 g of methyl 4-iodophenylpropionate used for the synthesis of the “intermediate compound 1”. The intermediate compound was then subjected to triarylation and chlorination, and the obtained chlorinated compound was subjected to homocoupling reaction to obtain the monomer compound (21).

Subsequently, the monomer compound (21) was polymerized in a manner substantially similar as Synthesis Example 1 to obtain the exemplary compound (13).

The molecular weight of the exemplary compound (13) was measured by gel permeation chromatography (GPC, manufactured by Tosoh Corporation, HLC-8120GPC); the weight average molecular weight (Mw) was 2.8×10⁴ (in terms of styrene), and the p value calculated from the molecular weight of the monomer was about 24.

The glass transition temperature (Tg) measured with a differential scanning calorimeter (manufactured by Seiko Instruments, Inc., Tg/DTA6200) was 158° C.

### Synthesis Example 5

An intermediate compound was synthesized in a manner substantially similar as Synthesis Example 1, except that 4-bromobiphenyl and methyl 3-(4-acetylaminophenyl) propionate ester were used in place of 37.5 g of acetoanilide and 96.6 g of methyl 4-iodophenylpropionate used for the synthesis of the “intermediate compound 1”. The intermediate compound was then subjected to triarylation and chlorination, and the obtained chlorinated compound was subjected to homocoupling reaction to obtain the monomer compound (24).

Subsequently, the monomer compound (24) was polymerized in a manner substantially similar as Synthesis Example 1 to obtain the exemplary compound (14).

The molecular weight of the exemplary compound (14) was measured by gel permeation chromatography (GPC, manufactured by Tosoh Corporation, HLC-8120GPC); the weight average molecular weight (Mw) was 3.1×10⁴ (in terms of styrene), and the p value calculated from the molecular weight of the monomer was about 32.

The glass transition temperature (Tg) measured with a differential scanning calorimeter (manufactured by Seiko Instruments, Inc., Tg/DTA6200) was 152° C.

### Synthesis Example 6

An intermediate compound was synthesized in a manner substantially similar as Synthesis Example 1, except that 3-methylacetoanilide and methyl 3-iodobiphenyl) propionate were used in place of 37.5 g of acetoanilide and 96.6 g of methyl 4-iodophenylpropionate used for the synthesis of the “intermediate compound 1”. The intermediate compound was then subjected to triarylation and chlorination, and the obtained chlorinated compound was subjected to homocoupling reaction to obtain the monomer compound (57).

Subsequently, the monomer compound (57) was polymerized in a manner substantially similar as Synthesis Example 1 to obtain the exemplary compound (31).

The molecular weight of the exemplary compound (31) was measured by gel permeation chromatography (GPC, manufactured by Tosoh Corporation, HLC-8120GPC); the weight average molecular weight (Mw) was 2.8×10⁴ (in terms of styrene), and the p value calculated from the molecular weight of the monomer was about 28.

The glass transition temperature (Tg) measured with a differential scanning calorimeter (manufactured by Seiko Instruments, Inc., Tg/DTA6200) was 153° C.

### Synthesis Example 7

An intermediate compound was synthesized in a manner substantially similar as Synthesis Example 1, except that t-buthylacetoanilide and methyl 3-iodobipheny propionate were used in place of 37.5 g of acetoanilide and 96.6 g of methyl 4-iodophenyl propionate used for the synthesis of the “intermediate compound 1”. The intermediate compound was then subjected to triarylation and chlorination, and the obtained chlorinated compound was subjected to homocoupling reaction to obtain the monomer compound (65).

Subsequently, the monomer compound (65) was polymerized in a manner substantially similar as Synthesis Example 1 to obtain the exemplary compound (33).

The molecular weight of the exemplary compound (33) was measured by gel permeation chromatography (GPC, manufactured by Tosoh Corporation, HLC-8120GPC); the weight average molecular weight (Mw) was 2.6×10⁴ (in terms of styrene), and the p value calculated from the molecular weight of the monomer was about 24.

The glass transition temperature (Tg) measured with a differential scanning calorimeter (manufactured by Seiko Instruments, Inc., Tg/DTA6200) was 146° C.

<Solubility of Charge-Transporting Polyester>

The exemplary compounds obtained above, and the below-described charge-transporting polymers used in Comparative Examples 2 to 4 were examined as to their solubility in various solvents. Solubility test was conducted in dichloroethane and chlorobenzene used in Examples and Comparative Examples, and in other solvents practically suitable for making organic EL elements. The solubility test was conducted as follows: 5 g of a compound was dissolved in 100 ml of a solvent, and the state was visually observed and evaluated according to the following criteria.

A: Dissolved without heating.

A to B: Dissolved under heating.

B: Partially dissolved.

The results are listed in Table 11.

TABLE 11

| | Solubility | | | |
|---|---|---|---|---|
| | Dichloro- | Chloro- | Cyclo- | |
| Compound | ethane | benzene | pentanone | Xylene |
| Exemplary compound (3) | A | A | A | A to B |
| Exemplary compound (5) | A | A | A | A to B |
| Exemplary compound (11) | A | A | A | A to B |
| Exemplary compound (13) | A | A | A | A to B |
| Exemplary compound (14) | A | A | A to B | B |
| Exemplary compound (31) | A | A | A | A to B |
| Exemplary compound (33) | A | A | A | A to B |
| PVK | A | A | A | B |
| Formula (XIII) | A | A | A | B |
| Formula (XIV) | A | A | A to B | B |

### Example 1

ITO (manufactured by Sanyoshinku Co., Ltd.) formed on a transparent insulating substrate is patterned by photolithography with a strip-shaped photomask and then etched thereby forming an strip-shaped ITO electrode (width 2 mm). Then, this ITO glass substrate is ultrasonicated sequentially in a neutral detergent solution, ultrapure water, acetone (for electronic industry, manufactured by Kanto Kagaku), and isopropanol (for electronic industry, manufactured by Kanto Kagaku) in this order for 5 minutes each, whereby the glass substrate is cleaned, followed by drying with a spin coater. A 5 wt % solution of the charge-transporting polyester [exemplary compound (3)] in monochlorobenzene is prepared, filtered though a 0.1-μm PTFE filter and applied onto the substrate by dipping to form a thin film having a thickness of 0.050 μm as a hole-transporting layer. The exemplary compound (X-1) is vapor-deposited as a light emitting material to form a light-emitting layer of 0.055 μm in thickness. After a metallic mask provided with strip-shaped holes is arranged, an LiF is deposited thereon to form a thin film having a thickness of 0.0001 μm, and aluminium is subsequently deposited thereon to form a thin film having a thickness of 0.150 μm, to form a back electrode having a width of 2 mm and a thickness of 0.15 μm such that the back electrode intersects with the ITO electrode. The effective area of the organic electroluminescent element formed is 0.04 cm².

### Example 2

A 10% by weight dichloroethane solution containing 1 part by weight of the charge-transporting polyester [exemplary compound (5)], 4 parts by weight of poly(N-vinyl carbazole), and 0.02 parts by weight of the exemplary compound (X-1) was prepared, and filtered through a 0.1-μm PTFE filter. The solution was applied by spin coating onto a glass substrate, which had been etched to form a strip-shaped ITO electrode, washed, and dried in a manner substantially similar as Example 1, to form a thin film having a thickness of 0.15 μm. After through drying, a metallic mask provided with strip-shaped holes was arranged, LiF was deposited thereon to form a thin film having a thickness of 0.0001 μm, and aluminum was subsequently deposited thereon to form a thin film having a thickness of 0.150 μm, to form a back electrode having a width of 2 mm and a thickness of 0.15 μm such that the back electrode intersects with the ITO electrode. The effective area of the organic electroluminescent element was 0.04 cm².

### Example 3

Onto an ITO glass substrate which had been etched, washed, and dried in a manner substantially similar as Example 1, the charge-transporting polyester [exemplary compound (11)] was applied in a manner substantially similar as Example 1 to form a hole-transporting layer having a thickness of 0.050 μm. Subsequently, a mixture of the exemplary compound (X-1) and the exemplary compound (XI-1) (mass ratio: 99/1) was applied to form a light-emitting layer having a thickness of 0.065 μm, and the exemplary compound (X-9) was applied to form an electron-transporting layer having a thickness of 0.030 μm. After through drying, a metallic mask provided with strip-shaped holes was arranged, LiF was deposited thereon to form a thin film having a thickness of 0.0001 μm, and aluminum was subsequently deposited thereon to form a thin film having a thickness of 0.150 μm, to form a back electrode having a width of 2 mm and a thickness of 0.15 μm such that the back electrode intersects with the ITO electrode. The effective area of the organic electroluminescent element was 0.04 cm².

### Example 4

Onto an ITO glass substrate which had been etched, washed, and dried in a manner substantially similar as Example 1, the charge-transporting polyester [exemplary compound (13)] was applied by ink jetting (piezoelectric ink jetting) in a manner substantially similar as Example 1 to form a hole-transporting layer having a thickness of 0.050 μm. Subsequently, the exemplary compound (X-16, n=8) containing 5% by weight of the exemplary compound (XI-5) was applied by spin coating to form a light-emitting layer having a thickness of 0.065 μm. After through drying, Ca was deposited thereon to form a thin film having a thickness of 0.08 μm, and aluminum was subsequently deposited thereon to form a thin film having a thickness of 0.15 μm, to form a back electrode having a width of 2 mm and a total thickness of 0.23 μm such that the back electrode intersects with the ITO electrode. The effective area of the organic electroluminescent element was 0.04 cm².

### Example 5

An organic electroluminescent element was made in a manner substantially similar as Example 2, except that the charge-transporting polyester [exemplary compound (14)] was used in place of the charge-transporting polyester [exemplary compound (5)] used in Example 2.

### Example 6

An organic electroluminescent element was made in a manner substantially similar as Example 3, except that the charge-transporting polyester [exemplary compound (31)] was used in place of the charge-transporting polyester [exemplary compound (II)] used in Example 3.

### Example 7

A 1.5% by weight dichloroethane solution containing the charge-transporting polyester [exemplary compound (33)] was prepared, and filtered through a 0.1-μm PTFE filter. The solution was applied by ink jetting onto an ITO glass substrate, which had been etched, washed, and dried in a manner substantially similar as Example 1, to form a thin film having a thickness of 0.05 μm. Subsequently, the exemplary compound (X-16, n=8) containing 5% by weight of the exemplary compound (XI-5) as the light-emitting material was applied by spin coating to form a light-emitting layer having a thickness of 0.050 μm. After through drying, Ca was deposited thereon to form a thin film having a thickness of 0.08 μm, and aluminum was subsequently deposited thereon to form a thin film having a thickness of 0.15 μm, to form a back electrode having a width of 2 mm and a total thickness of 0.23 μm such that the back electrode intersects with the ITO electrode. The effective area of the organic electroluminescent element was 0.04 cm².

### Example 8

Onto an ITO glass substrate which had been etched, washed, and dried in a manner substantially similar as Example 1, the exemplary compound (X-16, n=8) was applied to form a light-emitting layer having a thickness of 0.050 μm. A 1.0% by weight toluene solution containing the charge-transporting polyester [exemplary compound (11)] and 0.02 parts by weight of the exemplary compound (X-1) was prepared, and filtered through a 0.1-μm PTFE filter. The solution was applied onto the light-emitting layer by spin coating to form an electron-transporting layer having a thickness of 0.020 μm. After through drying, a metallic mask provided with strip-shaped holes was arranged, LiF was deposited thereon to form a thin film having a thickness of 0.0001 μm, and aluminum was subsequently deposited thereon to form a thin film having a thickness of 0.150 μm, to form a back electrode having a width of 2 mm and a thickness of 0.15 μm such that the back electrode intersects with the ITO electrode. The effective area of the organic electroluminescent element was 0.04 cm².

### Comparative Example 1

An organic EL element was made in a manner substantially similar as Example 1, except that the compound represented by the following Formula (XII) was used in place of the charge-transporting polyester [exemplary compound (3)] used in Example 1.

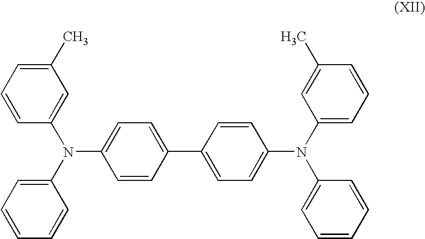

### Comparative Example 2

A 10% by weight dichloroethane solution containing 2 parts by weight of polyvinyl carbazole (PVK) as a charge-transporting polymer, 0.1 parts by weight of the exemplary compound (X-1) as a light-emitting material, and 1 part by weight of the compound (X-9) as an electron-transporting material was prepared, and filtered through a 0.1-μm PTFE filter. The solution was applied by dipping onto a glass substrate having a strip-shaped ITO electrode having a width of 2 mm, which had been formed by etching, to form a hole-transporting layer having a thickness of 0.15 μm. After through drying, a metallic mask provided with strip-shaped holes was arranged, LiF was deposited thereon to form a thin film having a thickness of 0.0001 μm, and aluminum was subsequently deposited thereon to form a thin film having a thickness of 0.150 μm, to form a back electrode having a width of 2 mm and a thickness of 0.15 μm such that the back electrode intersects with the ITO electrode. The effective area of the organic electroluminescent element was 0.04 cm².

### Comparative Example 3

A 10% by weight dichloroethane solution containing 2 parts by weight of the charge-transporting polymer represented by the following Formula (XIII), 0.1 parts by weight of the exemplary compound (X-1) as a light-emitting material, and 1 part by weight of the compound (X-9) as an electron-transporting material was prepared, and filtered through a 0.1-μm PTFE filter. The solution was applied by dipping onto a glass substrate having a strip-shaped ITO electrode having a width of 2 mm, which had been formed by etching, to form a hole-transporting layer having a thickness of 0.15 μm. After through drying, a metallic mask provided with strip-shaped holes was arranged, LiF was deposited thereon to form a thin film having a thickness of 0.0001 μm, and aluminum was subsequently deposited thereon to form a thin film having a thickness of 0.150 μm, to form a back electrode having a width of 2 mm and a thickness of 0.15 μm such that the back electrode intersects with the ITO electrode. The effective area of the organic electroluminescent element was 0.04 cm².

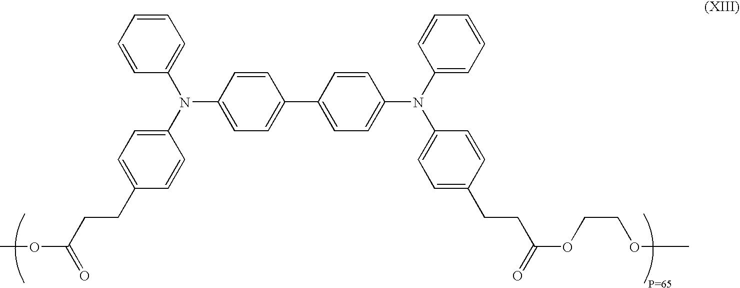

### Comparative Example 4

An organic EL element was made in a manner substantially similar as Example 1, except that the compound represented by the following Formula (XIV) (Tg: 145° C., weight average molecular weight: 5.1×10⁴) was used in place of the charge-transporting polyester [exemplary compound (3)] used in Example 1.

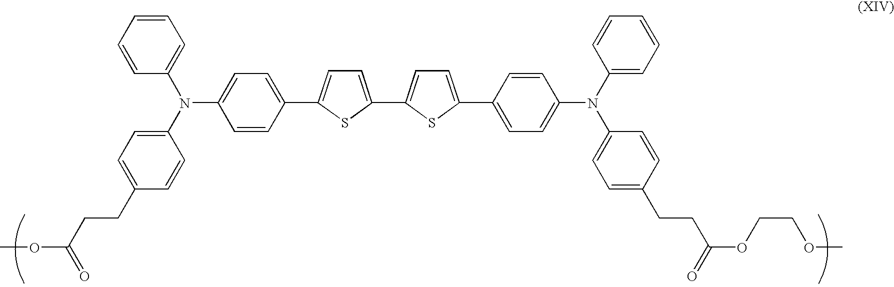

A direct current voltage was applied in a dry nitrogen atmosphere to the organic EL elements, which had been made as described above, with the ITO electrode side positive and the back electrode side negative.

The light-emitting properties was determined based on the driving current density when the initial luminance was 1000 cd/m² under a direct current driving system (DC driving). The luminescence life was evaluated based on the relative time to the drive time 1.0, which was assigned to the point when the luminance of the element of Comparative Example 1 (initial luminance L₀: 1000 cd/m²) became 0.5 in terms of luminance L/initial luminance L₀ at room temperature under a direct current driving system (DC driving), and on a voltage increment (=voltage/initial driving voltage) when the luminance of the element became 0.5 in terms of luminance L/initial luminance L₀. The results are listed in Table 12.

TABLE 12

| | Driving current | Voltage | |
|---|---|---|---|
| | density | increment | Relative time |
| | (mA/cm²) | (L/L0 = 0.5) | (L/L0 = 0.5) |
| Example 1 | 16.5 | 1.10 | 1.98 |
| Example 2 | 18.7 | 1.21 | 1.67 |
| Example 3 | 19.5 | 1.15 | 1.65 |
| Example 4 | 17.2 | 1.18 | 1.89 |
| Example 5 | 19.2 | 1.22 | 1.68 |
| Example 6 | 17.3 | 1.17 | 1.45 |
| Example 7 | 18.9 | 1.23 | 1.21 |
| Example 8 | 18.1 | 1.22 | 1.35 |
| Comparative Example 1 | 23.4 | 1.32 | 1.00 |
| Comparative Example 2 | 20.0 | 1.25 | 1.08 |
| Comparative Example 3 | 23.1 | 1.25 | 1.15 |
| Comparative Example 4 | 19.8 | 1.30 | 1.20 |

The results in Table 12 indicate that the organic electroluminescent elements of Examples 1 to 8 including the charge-transporting polyester in the exemplary embodiment, which has excellent stability and solubility, have a longer luminescence life than those including a conventional charge-transporting polymer.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated.

All publications, patent applications, and technical standards mentioned in this specification are herein incorporated by reference to the same extent as if such individual publication, patent application, or technical standard was specifically and individually indicated to be incorporated by reference. It is intended that the scope of the invention be defined by the following claims and their equivalents.

What is claimed is:

1. An organic electroluminescent element comprising an anode and a cathode that form a pair of electrodes, and at least one organic compound layer sandwiched between the pair of electrodes, at least one of the electrodes being transparent or translucent, and the at least one organic compound layer containing at least one charge-transporting polyester represented by Formula (I-1) or Formula (I-2): 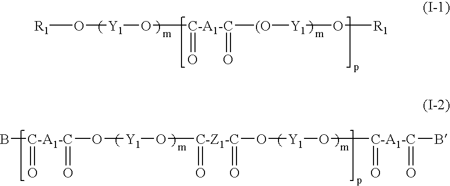
in Formula (I-1) and Formula (I-2), A₁ represents at least one structure selected from the structures represented by Formula (II-1) and Formula (II-2); R₁ represents a substituted or unsubstituted monovalent polynuclear aromatic hydrocarbon group having 2 to 10 aromatic rings, a substituted or unsubstituted monovalent condensed aromatic hydrocarbon group having 2 to 10 aromatic rings, a monovalent straight-chain hydrocarbon group having 1 to 6 carbon atoms, a monovalent branched hydrocarbon group having 2 to 10 carbon atoms, or a hydroxyl group; Y₁ represents a divalent alcohol residue; Z₁ represents a divalent carboxylic acid residue; m represents an integer of from 1 to 5; p represents an integer of from 5 to 5000; and B and B′ indicate groups represented by —O—(Y₁—O)ₘ—H or —O—(Y₁—O)ₘ—CO-Z₁-CO—OR₂ (wherein R₂ represents a hydrogen atom, an alkyl group, a substituted or unsubstituted aryl group, or a substituted or unsubstituted aralkyl group): 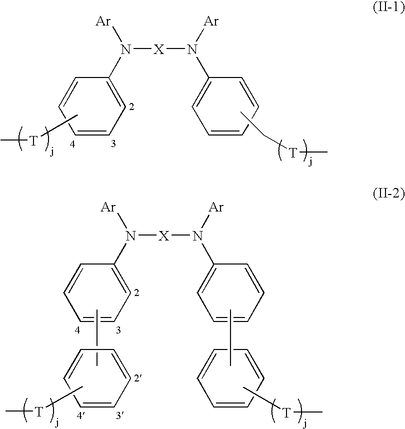
in Formula (II-1) and Formula (II-2), Ar represents a substituted or unsubstituted phenyl group, a substituted or unsubstituted monovalent polynuclear aromatic hydrocarbon having 2 to 10 aromatic rings, a substituted or unsubstituted monovalent condensed aromatic hydrocarbon having 2 to 10 aromatic rings, or a substituted or unsubstituted monovalent aromatic heterocycle; j represents 0 or 1; T represents a divalent straight-chain hydrocarbon group having 1 to 6 carbon atoms or a divalent branched hydrocarbon group having 2 to 10 carbon atoms; and X represents a group represented by Formula (III):

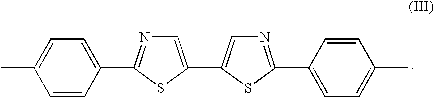

2. The organic electroluminescent element of claim 1, wherein:
the organic compound layer comprises a light-emitting layer and at least one layer selected from the group consisting of an electron-transporting layer and an electron injection layer, and wherein
at least one layer selected from the group consisting of the light-emitting layer, an electron-transporting layer and an electron injection layer comprises at least one charge-transporting polyester represented by Formula (I-1) or Formula (I-2).

3. The organic electroluminescent element of claim 1, wherein
the organic compound layer comprises a light-emitting layer and at least one layer selected from the group consisting of a hole-transporting layer and a hole injection layer, and wherein
at least one layer selected from the group consisting of the light-emitting layer, a hole-transporting layer and a hole injection layer comprises at least one charge-transporting polyester represented by Formula (I-1) or Formula (I-2).

4. The organic electroluminescent element of claim 1, wherein
the organic compound layer comprises
a light-emitting layer;
at least one layer selected from the group consisting of a hole-transporting layer and a hole injection layer; and
at least one layer selected from the group consisting of an electron-transporting layer and an electron injection layer; and wherein
at least one layer selected from the group consisting of the light-emitting layer, a hole-transporting layer, a hole injection layer, an electron-transporting layer, and an electron injection layer comprises at least one charge-transporting polyester represented by Formula (I-1) or Formula (I-2).

5. The organic electroluminescent element of claim 1, wherein the organic compound layer comprises only a light-emitting layer having charge-transporting properties, the light-emitting layer comprising at least one charge-transporting polyester represented by Formula (I-1) or Formula (I-2).

6. The organic electroluminescent element of claim 1, wherein Ar is a phenyl group, and Y₁ and Z₁, are selected from the groups represented by Formulae (IV-1) to (IV-6): 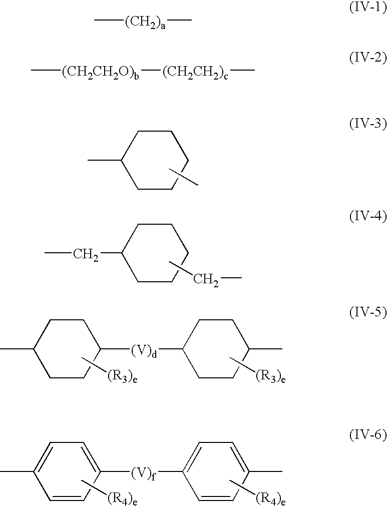
in Formulae (IV-1) to (IV-6), R₃ and R₄ each represent a hydrogen atom, a substituted or unsubstituted alkyl group having 1 to 4 carbon atoms, a substituted or unsubstituted alkoxy group having 1 to 4 carbon atoms, a substituted or unsubstituted phenyl group, a substituted or unsubstituted aralkyl group, or a halogen atom; a to c each independently represent an integer of from 1 to 10; e represents an integer of from 0 to 2; d and f each represent an integer of 0 or 1; and V represents a group represented by any one of the Formulae (V-1) to (V-12): 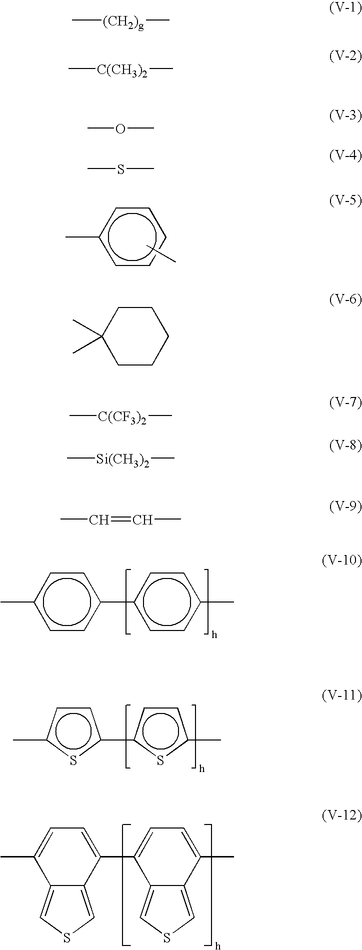
in Formulae (V-1), (V-10), (V-11), and (V-12), g represents an integer of from 1 to 20, and h represents an integer of from 0 to 10.

7. The organic electroluminescent element of claim 1, wherein the organic compound layer further comprises a hole-transporting material or an electron-transporting material different from the charge-transporting polyester.

8. The organic electroluminescent element of claim 7, wherein
the hole-transporting material is any one selected from the group consisting of tetraphenylenediamine derivatives, triphenylamine derivatives, carbazole derivatives, stilbene derivatives, spirofluorene derivatives, arylhydrazone derivatives, and porphyrin-based compounds; and
the electron-transporting material is any one selected from the group consisting of oxadiazole derivatives, nitro-substituted fluorenone derivatives, diphenoquinone derivatives, thiopyran dioxide derivatives, silole derivatives, organic metal chelate complexes, polynuclear or condensed aromatic cyclic compounds, perylene derivatives, triazole derivatives, and fluorenylidene methane derivatives.

9. The organic electroluminescent element of claim 2, wherein the electron injection layer comprises at least one of a metal, a metal fluoride, or a metal oxide.

10. The organic electroluminescent element of claim 3, wherein the hole injection layer comprises any one selected from the group consisting of triphenylamine derivatives, phenylene diamine derivatives, phthalocyanine derivatives, indanthrene derivatives, and polyalkylene dioxythiophene derivatives.

11. The organic electroluminescent element of claim 1, wherein the organic compound layer further comprises a light-emitting compound different from the charge-transporting polyester.

12. The organic electroluminescent element of claim 11, wherein the light-emitting compound is any one selected from the group consisting of organic metal chelate complexes, polynuclear or condensed aromatic cyclic compounds, perylene derivatives, coumarin derivatives, styryl arylene derivatives, silole derivatives, oxazole derivatives, oxathiazole derivatives, oxadiazole derivatives, polyparaphenylene derivatives, polyparaphenylene vinylene derivatives, polythiophene derivatives, and polyacetylene derivatives.

13. The organic electroluminescent element of claim 1, wherein the charge-transporting polyester further comprises a doped dye compound different from the light-emitting compound.

14. The organic electroluminescent element of claim 13, wherein the dye compound is at least one selected from the group consisting of coumarin derivatives, 4-dicyanmethylene-2-methyl-6-(4-dimethylaminostyryl)-4H-pyran (DCM) derivatives, quinacridone derivatives, perimidone derivatives, benzopyran derivatives, rhodamine derivatives, benzothioxanthene derivatives, rubrene derivatives, porphyrin derivatives, and metal complex compounds.

15. The organic electroluminescent element of claim 14, wherein the metal complex compound comprises at least one metal selected from the group consisting of ruthenium, rhodium, palladium, silver, rhenium, osmium, iridium, platinum, and gold.

16. A display device comprising organic electroluminescent elements and a driving unit that drives the organic electroluminescent elements, the organic electroluminescent elements having a matrix configuration or a segment configuration, and
each electroluminescent element comprises a pair of electrodes which are transparent or translucent, and an organic compound layer is sandwiched between the pair of electrodes, and the organic compound layer comprises at least one layer, and at least one layer of the organic compound layer includes at least one charge-transporting polyester of claim 1.
